(19) United States
(12) Patent Application Publication
(10) Pub. No.: US 2024/0213205 A1
(43) Pub. Date: Jun. 27, 2024

(54) SEMICONDUCTOR DEVICE PACKAGE

(71) Applicant: Advanced Semiconductor Engineering, Inc., Kaohsiung (TW)

(72) Inventors: Jung Jui KANG, Kaohsiung (TW); Shih-Yuan SUN, Kaohsiung (TW); Chieh-Chen FU, Kaohsiung (TW)

(73) Assignee: Advanced Semiconductor Engineering, Inc., Kaohsiung (TW)

(21) Appl. No.: 18/088,498

(22) Filed: Dec. 23, 2022

(51) Int. Cl. H01L 23/00; G02B 6/42; H01L 23/31

(52) U.S. Cl. CPC H01L 24/29; G02B 6/4239; G02B 6/424; G02B 6/4253; H01L 23/3157; H01L 24/16; H01L 24/32; H01L 24/73; H01L 2224/16227; H01L 2224/26175; H01L 2224/32225; H01L 2224/73204

(57) ABSTRACT

A package is provided. The package includes a carrier, a component, and a first protective element. The component is disposed over the carrier and having a side surface configured for optically coupling. The first protective element is disposed between the carrier and the component. The side surface of the component is free from being in contact with the first protective element.

### BACKGROUND

### 1. Technical Field

The present disclosure relates generally to a semiconductor device package.

### 2. Description of the Related Art

Silicon photonics and optical engines with integration of at least an electronic IC (EIC) and a photonic IC (PIC) have advantages of high transmission speed and low power loss, and thus are applied in various areas. The PIC may be mounted to a carrier and a filling material will be formed between the PIC and the carrier. However, the filling material may overflow to a side surface of the PIC, which adversely affects the connection between the PIC and an external optical fiber.

### SUMMARY

In one or more embodiments, a package includes a carrier, a component, and a first protective element. The component is disposed over the carrier and having a side surface configured for optically coupling. The first protective element is disposed between the carrier and the component. The side surface of the component is free from being in contact with the first protective element.

In one or more embodiments, a semiconductor package includes a carrier, a component, and a plurality of interconnection elements. The component is disposed over the carrier and has a side surface configured for external communication. The plurality of interconnection elements connects the carrier and the component, and is encapsulated by a protection element. The side surface of the component is free from being in contact with the protective element.

In one or more embodiments, a semiconductor device package includes a carrier, a component, and a protective element. The component is disposed over the carrier. The protective element is between the carrier and the component. A region is defined by overlapping between the carrier and the component and comprises: a first region, accommodating a plurality of interconnection elements encapsulated by the protective element and a second region, accommodating a portion of the protective element and none of the plurality of interconnection elements.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1 is a top view of a semiconductor device package in accordance with some embodiments of the present disclosure;

FIG. 1A is a cross-section of a semiconductor device package in accordance with some embodiments of the present disclosure;

FIG. 1B is a top view of a portion of a semiconductor device package in accordance with some embodiments of the present disclosure;

FIG. 1C is a cross-section of a semiconductor device package in accordance with some embodiments of the present disclosure;

FIG. 1C-1 is a cross-section of a semiconductor device package in accordance with some embodiments of the present disclosure;

FIG. 1C-2 is a cross-section of a semiconductor device package in accordance with some embodiments of the present disclosure;

FIG. 1D is a top view of a portion of a semiconductor device package in accordance with some embodiments of the present disclosure;

FIG. 1D-1 is a top view of a portion of a semiconductor device package in accordance with some embodiments of the present disclosure;

FIG. 1E is a cross-section of a semiconductor device package in accordance with some embodiments of the present disclosure;

FIG. 1F is a top view of a portion of a semiconductor device package in accordance with some embodiments of the present disclosure;

FIG. 1G is a top view of a portion of a semiconductor device package in accordance with some embodiments of the present disclosure;

FIG. 1H is a cross-section of a semiconductor device package in accordance with some embodiments of the present disclosure;

FIG. 1I is a cross-section of a semiconductor device package in accordance with some embodiments of the present disclosure;

FIG. 2 is a top view of a semiconductor device package in accordance with some embodiments of the present disclosure;

FIG. 2-1 is a top view of a semiconductor device package in accordance with some embodiments of the present disclosure;

FIG. 2A is a cross-section of a semiconductor device package in accordance with some embodiments of the present disclosure;

FIG. 2B is a cross-section of a semiconductor device package in accordance with some embodiments of the present disclosure;

FIG. 2C is a cross-section of a semiconductor device package in accordance with some embodiments of the present disclosure;

FIG. 2D is a cross-section of a semiconductor device package in accordance with some embodiments of the present disclosure;

FIG. 2E is a cross-section of a semiconductor device package in accordance with some embodiments of the present disclosure;

FIG. 2F is a cross-section of a semiconductor device package in accordance with some embodiments of the present disclosure;

FIG. 2G is a cross-section of a semiconductor device package in accordance with some embodiments of the present disclosure;

FIG. 2H is a cross-section of a semiconductor device package in accordance with some embodiments of the present disclosure;

FIG. 3 is a top view of a semiconductor device package in accordance with some embodiments of the present disclosure;

FIG. 3-1 is a top view of a semiconductor device package in accordance with some embodiments of the present disclosure;

FIG. 3A is a cross-section of a semiconductor device package in accordance with some embodiments of the present disclosure;

FIG. 4 is a top view of a semiconductor device package in accordance with some embodiments of the present disclosure;

FIG. 4A is a cross-section of a semiconductor device package in accordance with some embodiments of the present disclosure;

FIG. 5 is a top view of a semiconductor device package in accordance with some embodiments of the present disclosure;

FIG. 5A is a cross-section of a semiconductor device package in accordance with some embodiments of the present disclosure;

FIG. 5B is a cross-section of a semiconductor device package in accordance with some embodiments of the present disclosure;

FIG. 5C is a cross-section of a semiconductor device package in accordance with some embodiments of the present disclosure.

FIG. 6A illustrates one or more stages of an example of a method for manufacturing a semiconductor device package according to some embodiments of the present disclosure.

FIG. 6B illustrates one or more stages of an example of a method for manufacturing a semiconductor device package according to some embodiments of the present disclosure.

FIG. 6C illustrates one or more stages of an example of a method for manufacturing a semiconductor device package according to some embodiments of the present disclosure.

FIG. 6D illustrates one or more stages of an example of a method for manufacturing a semiconductor device package according to some embodiments of the present disclosure.

FIG. 6E illustrates one or more stages of an example of a method for manufacturing a semiconductor device package according to some embodiments of the present disclosure.

FIG. 6F illustrates one or more stages of an example of a method for manufacturing a semiconductor device package according to some embodiments of the present disclosure.

FIG. 6G illustrates one or more stages of an example of a method for manufacturing a semiconductor device package according to some embodiments of the present disclosure.

FIG. 7A illustrates one or more stages of an example of a method for manufacturing a semiconductor device package according to some embodiments of the present disclosure.

FIG. 7B illustrates one or more stages of an example of a method for manufacturing a semiconductor device package according to some embodiments of the present disclosure.

FIG. 7C illustrates one or more stages of an example of a method for manufacturing a semiconductor device package according to some embodiments of the present disclosure.

FIG. 7D illustrates one or more stages of an example of a method for manufacturing a semiconductor device package according to some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

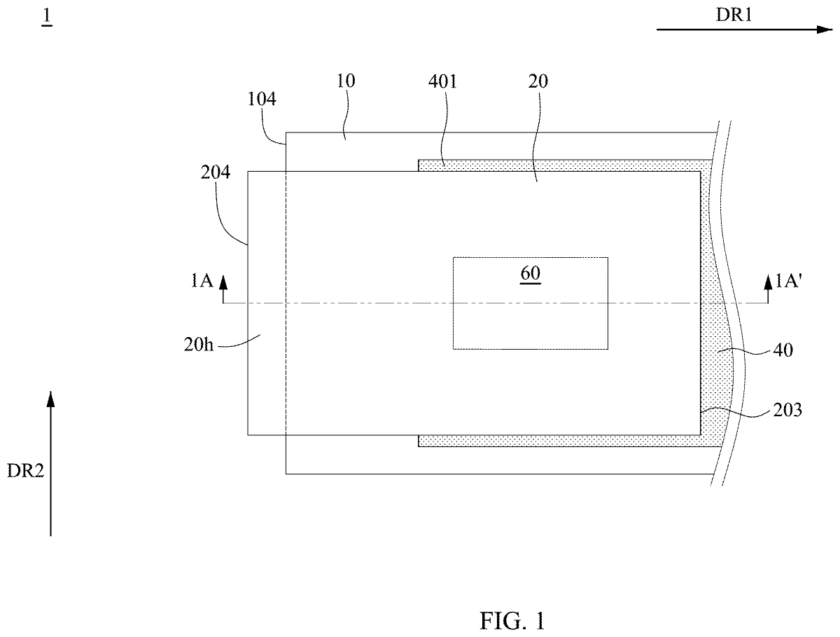

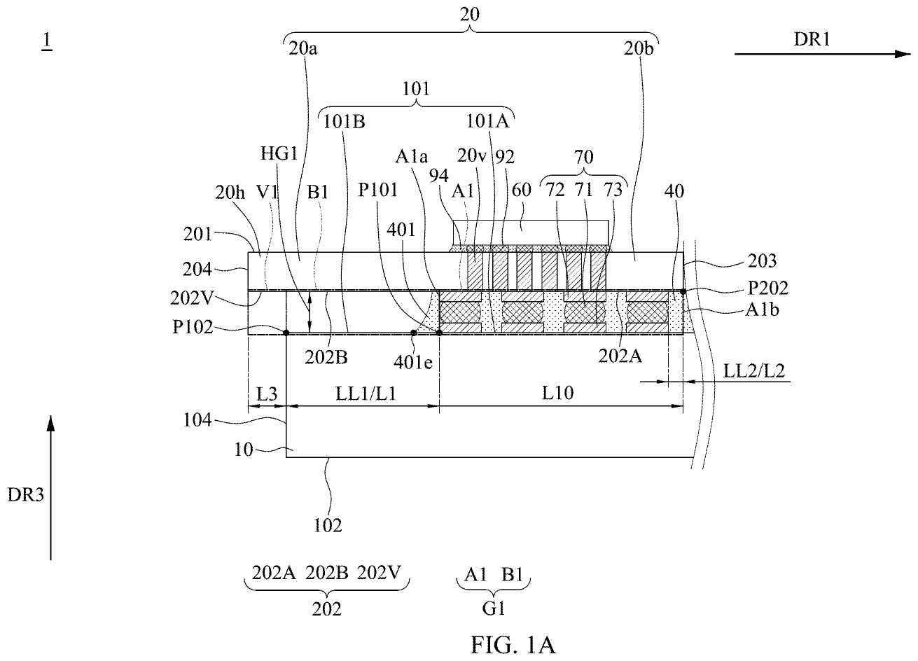

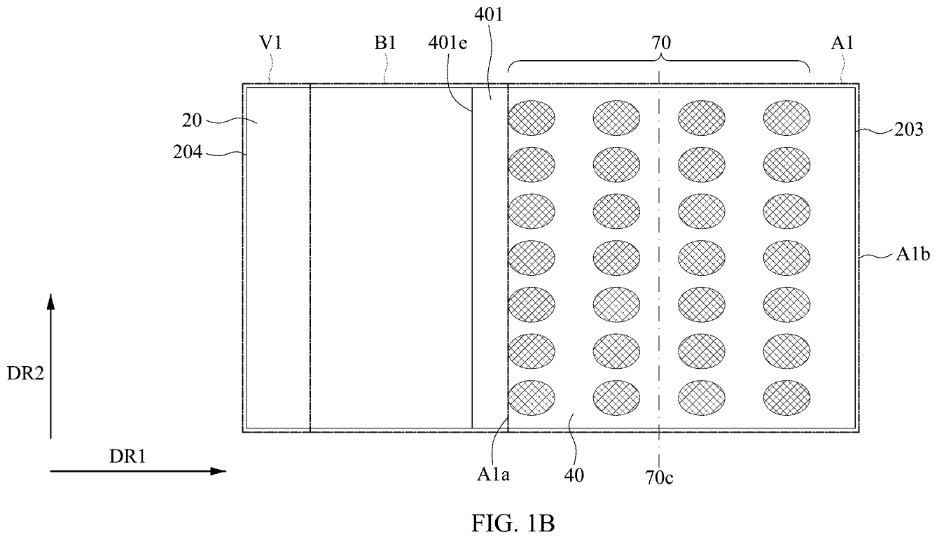

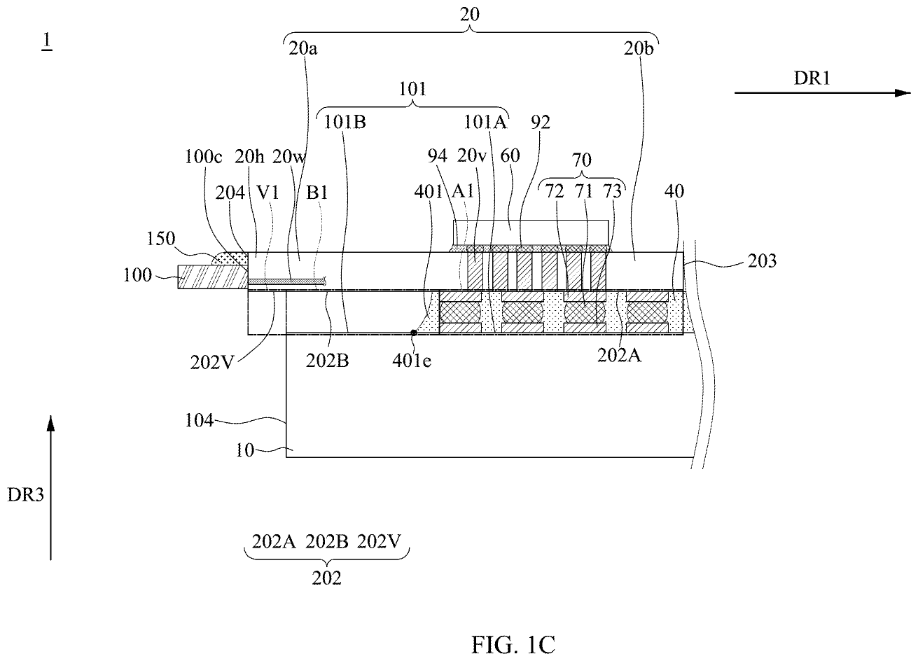

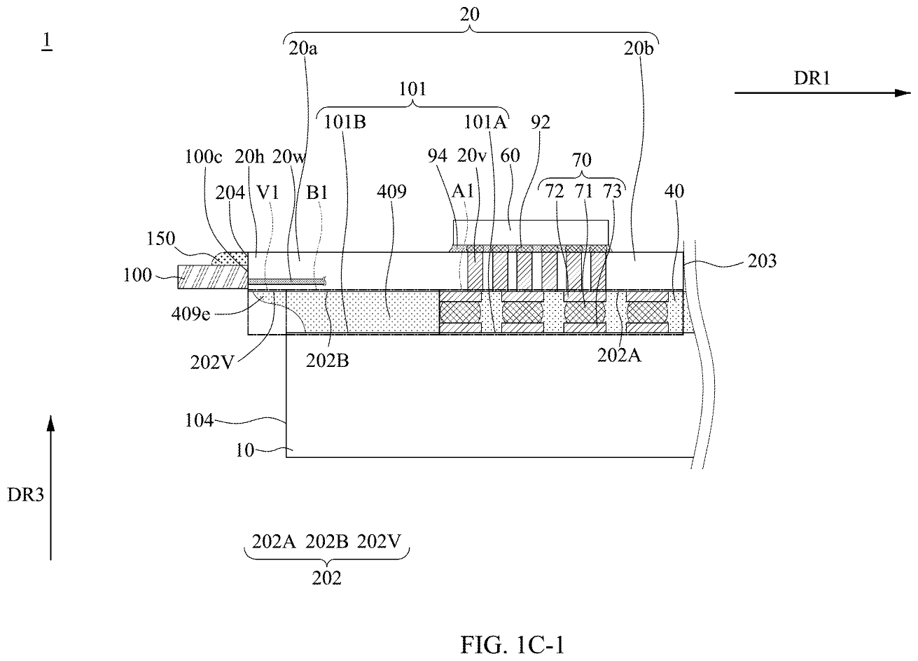

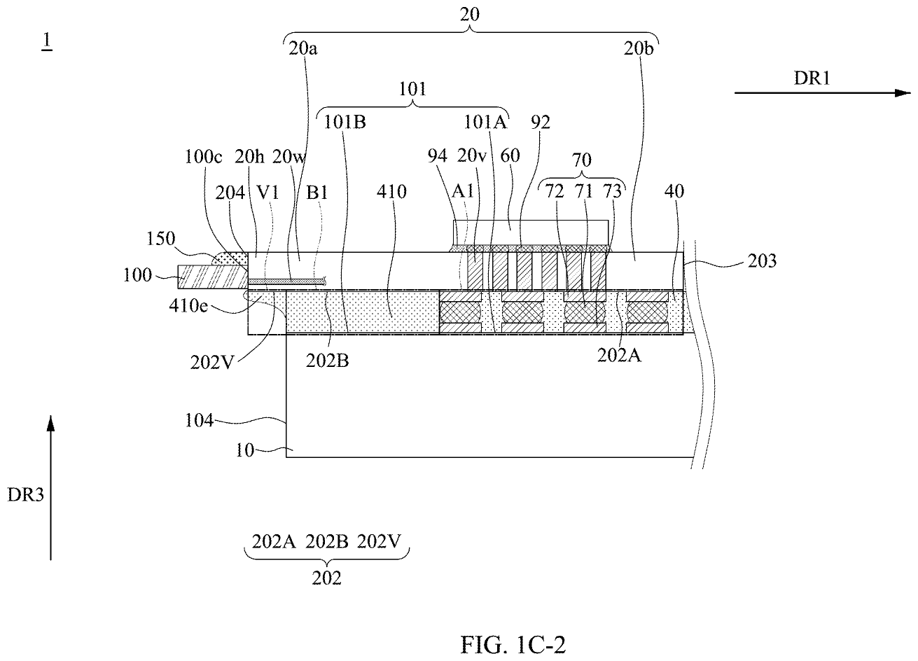

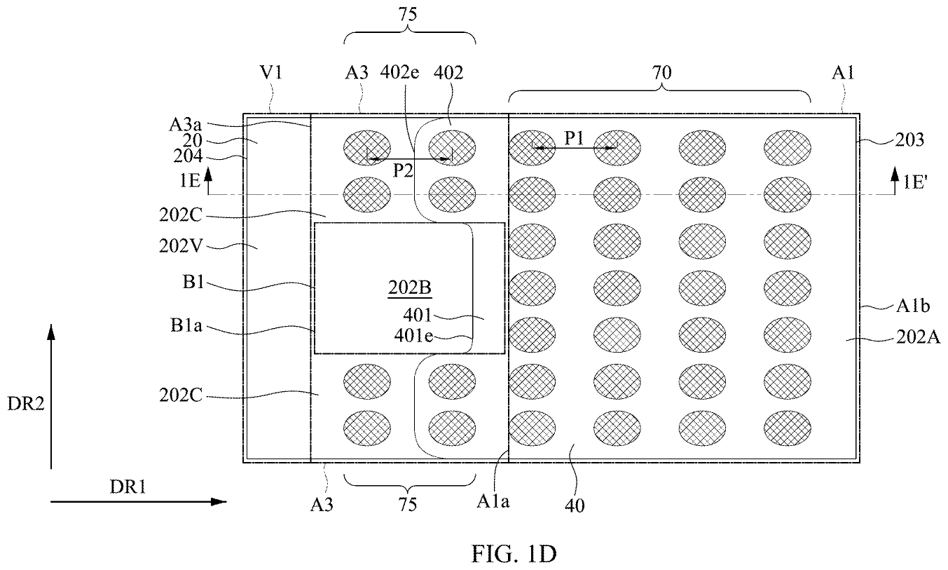

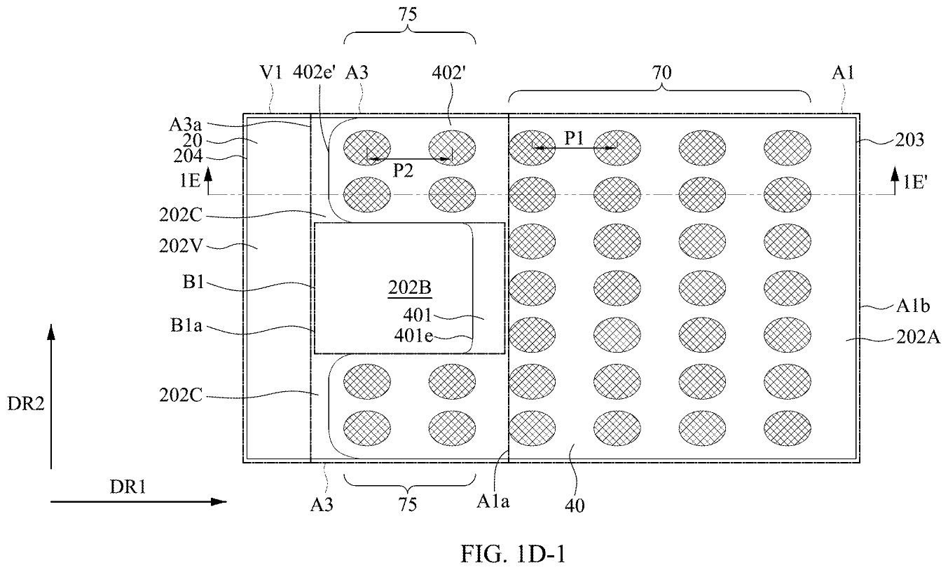

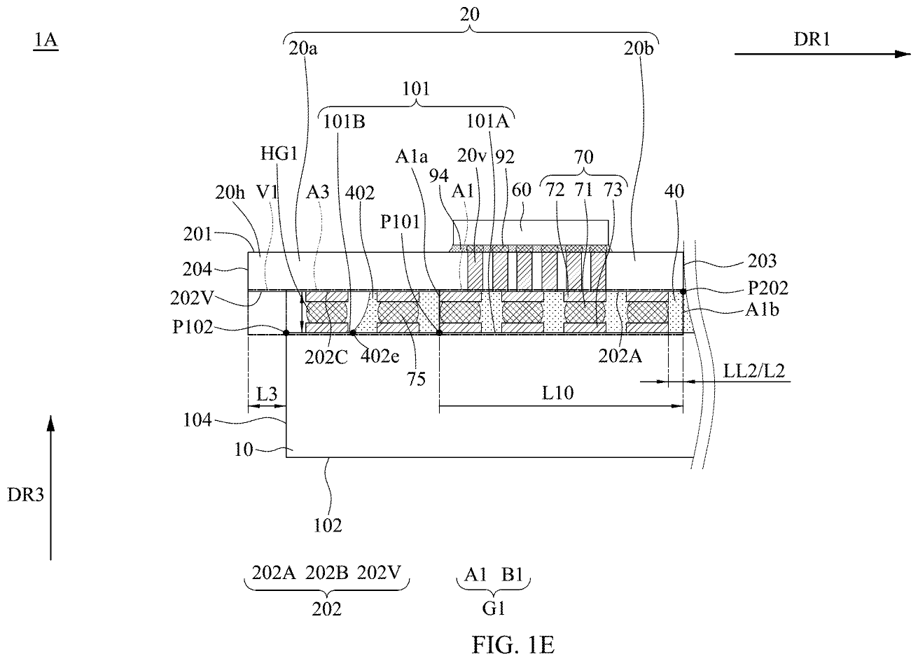

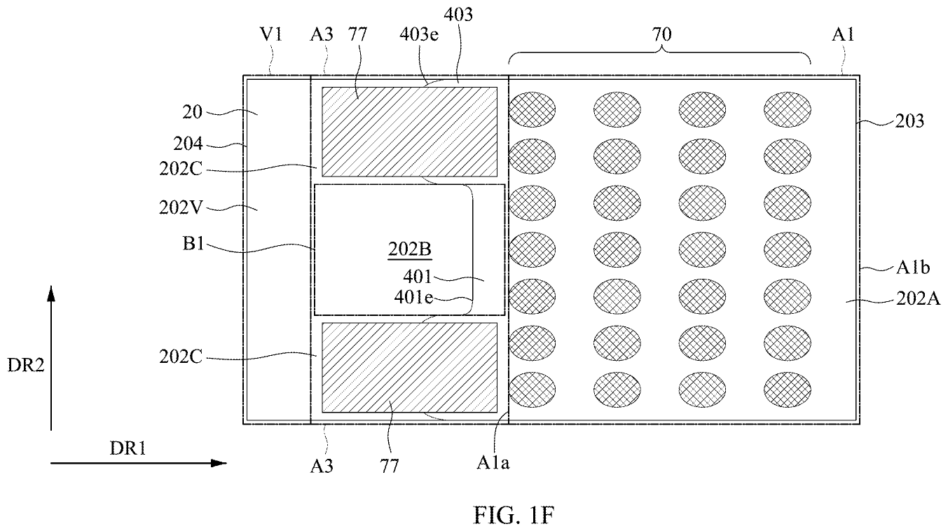

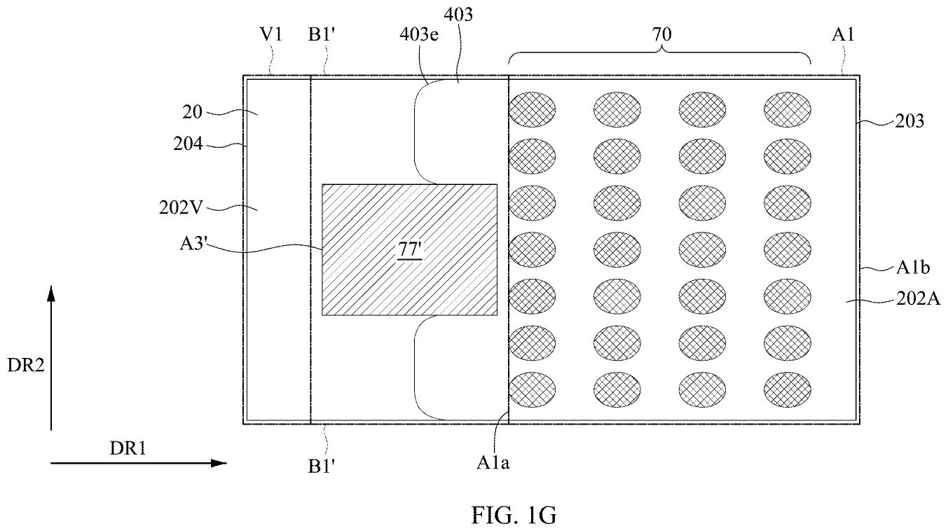

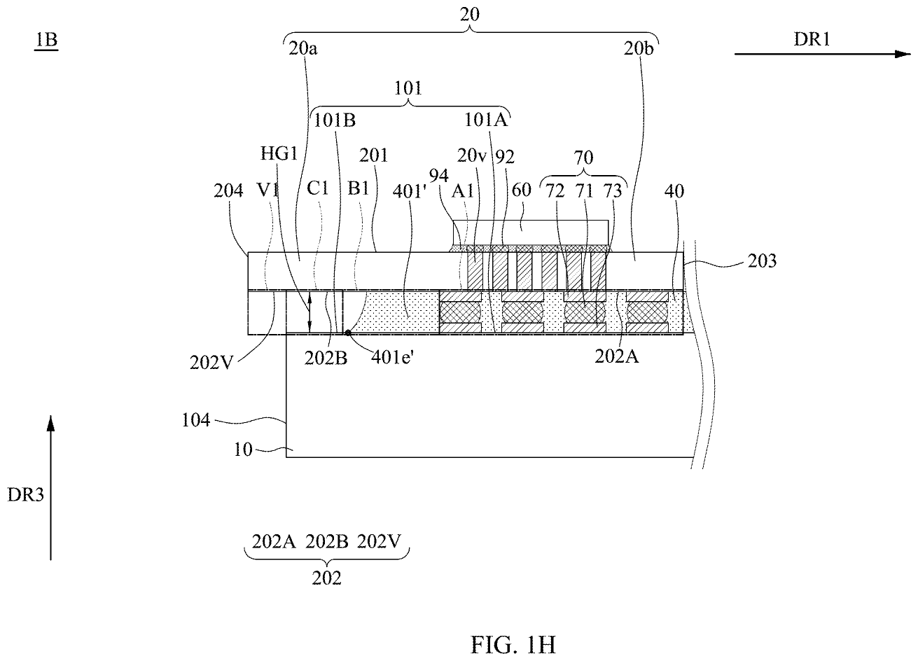

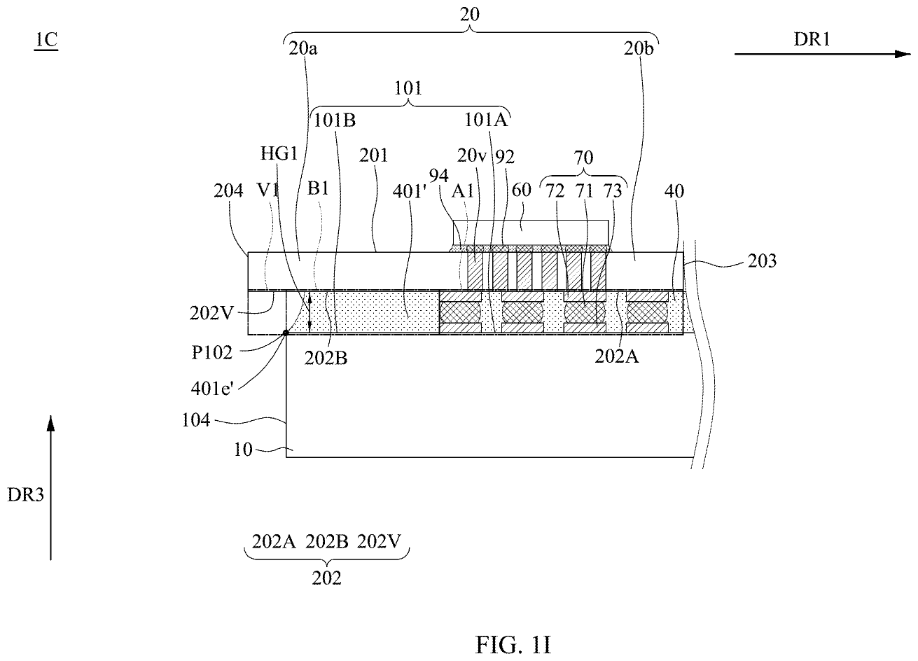

FIG. 1 is a top view of a semiconductor device package (a semiconductor package or a package) 1 in accordance with some embodiments of the present disclosure. FIG. 1A is a cross-section of the semiconductor device package 1 in accordance with some embodiments of the present disclosure. In some embodiments, FIG. 1A is a cross-section along line 1A-1A′ in FIG. 1. The semiconductor device package 1 includes a carrier 10, a component 20, a protective element 40, and a component 60.

The carrier 10 may have a surface (or an upper surface) 101 facing the component 20 and a surface (or a bottom surface) 102 opposite to the surface 101. The carrier 10 may have a side surface 104 extending between the surfaces 101 and 102. The carrier 10 may include an interposer. The carrier 10 may include, for example, a printed circuit board, such as a paper-based copper foil laminate, a composite copper foil laminate, or a polymer-impregnated glass-fiber-based copper foil laminate. The carrier 10 may include an interconnection structure, which may include such as a plurality of conductive traces and/or a plurality of conductive vias. The interconnection structure may include a redistribution layer (RDL) and/or a grounding element. In some embodiments, the carrier 10 includes a ceramic material or a metal plate. In some embodiments, the carrier 10 may include a substrate, such as an organic substrate or a leadframe. In some embodiments, the carrier 10 may include a two-layer substrate which includes a core layer and a conductive material and/or structure disposed on an upper surface (or a top surface) and a lower surface (or a bottom surface) of the carrier 10. The conductive material and/or structure may include a plurality of traces. The carrier 10 may include one or more conductive pads in proximity to, adjacent to, or embedded in and exposed by an upper surface and/or a lower surface of the carrier 10. The carrier 10 may include a solder resist (not shown in FIG. 1) on the upper surface (e.g., the surface 101) and/or the lower surface (e.g., the surface 102) of the carrier 10 to fully expose or to expose at least a portion of the conductive pads for electrical connection.

The component (or the semiconductor chip) 20 may be disposed over the carrier 10. In some embodiments, the component 20 is flip-chip bonded to the carrier 10. In some embodiments, a portion of the component 20 protrudes outwards from a side surface of the carrier 10. The component 20 may have a surface (or an upper surface) 201 and a surface (or a bottom surface) 202 opposite to the surface 201. The surface 202 of the component 20 may face the surface 101 of the carrier 10. The component 20 may have a side surface 203 and a side surface 204 opposite to the side surface 203. The edges 203 and 204 of the component 20 may extend between the surface 201 and the surface 202 of the component 20, as shown in FIG. 1A. The side surface 203 may extend along a direction (or along an orientation) DR2, as illustrated in FIG. 1. In some embodiments, the side surface 204 may extend along the direction DR2. The side surface 204 of the component 20 and the side surface 104 of the carrier 10 may face the same direction. The side surface 104 of the carrier 10 may be closer to the side surface 204 than the side surface 203.

The component 20 may have a portion (or an overhang portion) 20h having the side surface 204. The portion 20h of the component 20 may protrude from the side surface 104 of the carrier 10 from a top view, as illustrated in FIG. 1. The portion 20h of the component 20 may project over the carrier 10. The portion 20h of the component 20 may have no projecting area on the surface 101 of the carrier 10 in a direction (or an orientation) DR3 substantially normal to the direction DR1 and DR2.

In some embodiments, the component 20 includes a photonic component, such as a photonic IC (PIC). In some embodiments, the component 20 may include a photonic interposer stacked over the carrier 10. In some embodiments, the component 20 may include an interposer and the component (or the semiconductor die) 60. The semiconductor device package 1 may have a two-and-a-half dimensional (2.5D) structure. The component 20 may include at least one waveguide (not shown) configured to transmit optical signals between an external component (e.g., an optical fiber) and the semiconductor device package 1. In some embodiments, the portion (or the overhang portion) 20h of the component 20 may be connected to an optical fiber.

The protective element (or the first protective element) 40 may be disposed over the carrier 10. In some embodiments, the protective element 40 is between the component 20 and the carrier 10. In some embodiments, the protective element 40 includes a portion covering a portion of the component 20. The protective element 40 may be or include an encapsulant. The protective element 40 may include an epoxy resin having fillers, a molding compound (e.g., an epoxy molding compound or other molding compound), polyimide, a phenolic compound or material, a material with a silicone dispersed therein, or a combination thereof.

In some embodiments, the semiconductor device package 1 further includes a plurality of interconnection elements 70 between the carrier 10 and the component 20. In some embodiments, the interconnection elements 70 are on the carrier 10. In some embodiments, the protective element 40 covers or encapsulates the interconnection elements 70. In some embodiments, the interconnection elements 70 may include one or more conductive bumps, one or more conductive pads, one or more under bump metals (UBMs), one or more solder balls, one or more conductive studs, or a combination thereof. For example, the interconnection element 70 may include conductive pads 72 and 73 and a solder ball 71 disposed between and connected to the conductive pads. In some embodiments, the interconnection element 70 may include Ag, Al, Cu, or an alloy thereof.

According to some embodiments of the present disclosure, the interconnection elements may 70 include solder or soldering materials (e.g., the solder balls 71) may be configured to self-align the components 20 to the carrier 10. With the conductive pads 72 pre-formed on predetermined positions of the carrier 10 and the conductive pads 73 pre-formed on predetermined positions of the components 20, the solders 71 may serve to align the components 20 to the carrier 10 by self-aligning the conductive pads 73 to the conductive pads 72 when the solders 71 are melted during bonding. Thus, the alignment accuracy of the components 20 to the carrier 10 can be increased.

In some embodiments, the protective element 40 has an edge 401e under a first region 20a of the component 20. The first region 20a may be between the side surface 204 of the component 20 and a second region 20b of the component 20. The plurality of interconnection elements 70 may be under the second region 20a of the component 20.

Referring to FIG. 1A, the surface 202 of the component 20 and the surface 101 of the carrier 10 may define a gap G1. The surface 101 of the carrier 10 may have a portion (or a first portion) 101A and a portion (or a second portion) 101B. The portion 101A may be adjacent to the portion 101B. The portion 101A may connect the portion 101B. The surface 202 of the component 20 may have a portion (or a first portion) 202A, and a portion (or a second portion) 202B, and a portion (or a third portion) 202V. The portion 202A may be adjacent to the portion 202B. The portion 202A may connect the portion 202B. The portion 202B may be closer to the side surface 204 of the component 20 than the portion 202A. The portion 101A of the surface 101 may be under the portion 202A of the surface 202. The portion 101A of the surface 101 may be below the portion 202A of the surface 202. The portion 101A of the surface 101 may correspond to the portion 202A of the surface 202. The portion 101B of the surface 101 may be under the portion 202B of the surface 202. The portion 101B of the surface 101 may be below the portion 202B of the surface 202. The portion 101B of the surface 101 may correspond to the portion 202B of the surface 202. The portion (or the overhang portion) 20h of the component 20 may have the portion 202V of the surface 202. The portion 202V of the surface 202 may be in conjunction to the side surface 204 of the component 20. The portion 202V of the surface 202 of the component 20 may have no projecting area on the surface 101 of the carrier 10. The portion 202V may laterally extend beyond the side surface 104 of the carrier 10.

The portion 202A of the surface 202 of the component 20 may be connected to the interconnection elements 70. The portion 202A of the surface 202 of the component 20 may connect to the side surface 203 of the component 20. The portion 101A of the surface 101 of the carrier 10 may be connected to the interconnection elements 70. The portion 202A of the surface 202 of the component 20 and/or the portion 101A of the surface 101 of the carrier 10 may be in contact with the interconnection elements 70. The portion 202A of the surface 202 of the component 20 and/or the portion 101A of the surface 101 of the carrier 10 may be in contact with the protective element 40.

The portion 202A of the surface 202 and the portion 101A of the surface 101 may define a region (or a first region) A1. The region A1 may be included in the gap G1. The region A1 may be a space (or a gap) between the portion 202A of the surface 202 and the portion 101A of the surface 101. The region A1 may be under the portion 202A of the surface 202. The interconnection elements 70 may be disposed in the region A1. In other words, the distribution of the interconnection elements 70 may define the region A1. The region A1 may have a length L10 in the direction DR1. The length L10 may equal to a length of the portion 202A or the portion 101A. In some embodiments, the length L10 may be defined by the leftmost of the interconnection elements 70 and a turning point P202 of the side surface 203 and the surface 202B of the component 2 in the direction DR1. The leftmost of the interconnection elements 70 may be the outermost of the interconnection elements 70 that is closer to the side surface 204 of the component 20 than the side surface 203. A portion of the region A1 may have a length L2. The length L2 may be defined by the turning point P202 and the rightmost of the interconnection elements 70. The leftmost of the interconnection elements 70 may be the outermost of the interconnection elements 70 that is closer to the side surface 203 of the component 20 than to the side surface 204.

The portion 101B of the surface 101 of the carrier 10 may connect to the side surface 104 of the carrier 10. The portion 101B of the carrier 10 may have an edge (or point) P101 connected to the portion 101A. The portion 202B of the surface 202 of the component 20 may be free from contact with the interconnection elements 70. The portion 101B of the surface 101 of the carrier 10 may be free from contact with the interconnection elements 70.

The portion 202B of the surface 202 may have a length L1 in the direction DR1 parallel to the surface 101 of the carrier 10. The portion 202B of the surface 202 and the portion 101B of the surface 101 may define a region (or a second region) B1. The region B1 may be included in the gap G1. The region B1 may be a clearance region of the interconnection elements 70. In some embodiments, no interconnection elements are disposed in the region B1. In other words, the region B1 may be defined by position arrangement of the plurality of interconnection elements 70 and accommodate none of the plurality of interconnection elements. The region B1 may be a space between the portion 202B of the surface 202 and the portion 101B of the surface 101. The region B1 may be under the portion 202B of the surface 202. The region B1 may have the length L1. The length L1 may be defined by a turning point P102 between the side surface 104 and the portion 101B and the point P101. The region B1 may have a height HG1. The height HG1 may be defined as a distance between the portion 202B of the surface 202 and the portion 101B of the surface 101 in the direction DR3. The height HG1 may be less than the length L1. In some embodiments, the height HG1 may be in a range from around 60 μm to around 70 μm.

In some embodiments, the region A1 and the region B1 may be included in a region defined by overlapping between the carrier 10 and the component 20. The region A1 may accommodate the plurality of interconnection elements 70. The region B1 may be void of any of the interconnection elements. In some embodiments, the region A1 may accommodate the plurality of interconnection elements 70 encapsulated by the protective element 40. The region B1 may accommodate a portion (e.g., the portion 401) of the protective element 40 and none of the plurality of interconnection elements. An area of the region A1 may be greater than an area of the region B1. The region B1 may have a region being void of any of the interconnection elements 70 or the protective element 40. The warpage of the component 20 may be in a range less than +/−8 μm.

In some embodiments, the length L2 of the region A1 and the length L1 of the region B1 may be different. The length L10 of the region A1 and the length L1 of the region B1 may be different. The length L1 of the region B1 may exceed the length L2 of the region A1. The length L1 of the region B1 may be, for example, around 350 μm, 400 μm, 450 μm, 500 μm, 550 μm, 600 μm, 650 μm, 700 μm or more. The length L1 may be around 5-15 times the height HG1.

The portion 202V of the surface 202 of the component 20 (or the overhang portion 20h) may have a length L3. The length L3 may be less than the length L1. The length L1 may be greater than the length L3. The portion 202V of the surface 202 of the component 20 may define a region V1. The region V1 may be under the portion 202V of the surface 202. The region V1 may be between the portion 202V of the surface 202 of the component 20 and an imaginary plane extending from the surface 101 of the carrier. The region V1 may have the length L3.

As shown in FIG. 1A, the region B1 may exclude any interconnection elements. The interconnection elements 70 may be closer to the side surface 203 of the component 20 than to the side surface 204. In particular, a spacing LL1 between the side surface 204 and the interconnection elements 70 at a first side Ala of the region A1 facing the side surface 204 may be greater than a spacing LL2 between the side surface 203 and the interconnection elements 70 at a side Alb of the region A1 facing the side surface 203. In some embodiments, the distance (e.g., the length L1) between the side surface 203 and the rightmost interconnection element 70 is shorter than the distance (e.g., the length L2) between the side surface 204 and the leftmost interconnection element 70.

FIG. 1B is a top view of a portion of a semiconductor device package (e.g., the semiconductor device package 1) in accordance with some embodiments of the present disclosure. FIG. 1B illustrates the component 20, the conductive elements 70, and the protective element 40, and omits other components as illustrated in FIGS. 1 and 1A for the demonstration of the relationship of the conductive elements and the regions A1, B1, and V1.

The conductive elements 70 may include an array. The array of the conductive elements 70 may have a central line 70c closer to the side surface 203 than to the side surface 204. The conductive elements 70 may include a C4 bump array. The conductive elements 70 may be located in the region A1. On the other hand, the region B1 may lack a conductive element. The distribution of the conductive elements 70 may be designed to have a clearance region in the region B1. Accordingly, the portion 202B of the surface 202 of the component 20 may be designed to have no conductive pads for connecting conductive elements.

During the formation of the protective element 40, a protective material may be applied by syringe equipment (not shown), for example, towards a gap (e.g., the region A1) defined by the component 20 and the carrier 10 from an upper edge of the component 20 from a top view (e.g., FIG. 1). Referring again to FIG. 1A, the protective material may flow through the gap G1 (e.g., the region A1) by the capillary effect presents between the surface 202 of the component 20 and the surface 101 of the carrier 10 to form the protective element 40 in the region A1. The protective element 40 may fill the region A1. The protective material may cover or encapsulate the interconnection elements 70. A portion of the protective material my overflow beyond the outermost interconnection element 70 (e.g., the leftmost interconnection element 70), prior to curing, to form a portion (or an edge portion) 401 of the protective element 40 in the region B1 as shown in FIG. 1A and FIG. 1B. The protective element 40 may partially fill the region B1. The portion 401 may be between the interconnection elements 70 and the side surface 204 of the component 20. The portion 401 may be closer to the interconnection elements 70 than to the side surface 204 of the component 20. The interconnection elements 70 creates a plurality of small gaps in the region A1. Hence, the region A1 may be configured to exert a greater capillary force than the region B1 on the protective element 40 prior to curing. In other words, the region B1 with no interconnection elements exerts a smaller capillary force on the protective element 40 prior to curing than the region A1. The portion 401 may have an end 401e closer to the point P101 than the turning point P102. The edge 401e may be between the side surface 204 of the component and one of the plurality of interconnection elements 70 being closest to the side surface 104 of the carrier 10. The portion 401 may be closer to the region B1 than the region V1.

The portion 401 may overlap the surface 101 of the carrier from the top view. The region B1 with the relatively increased length L1 provides a buffer zone for the overflow of the protective material during the formation of the protective element 40. As such, the portion (or the overhang portion) 20h of the component 20 may not contact the protective element 40 (or the portion 401). The region B1 may be configured to accommodate the portion 401 of the protective element 40. Furthermore, the connection elements (e.g., 70) in region A1 can increase the surface area in contact with the protective element 40 and thus exerting a greater capillary force on the protective element 40 prior to curing. Therefore, the region B1 with no connection elements, compared to region A1, demonstrates a smaller surface area in contact with the protective element 40 and thus only exerting smaller capillary force on the protective element 40 prior to curing. As such, that the protective element 40 prior to curing (e.g., the protective material) spread less extensively in the region B1 than in the region A1. The side surface 204 of the component 20 may not contact the protective element 40 (or the portion 401). The side surface 204 may be configured for external communication (electrical, optical, thermal, radiated, etc.). The region B1 allows for more buffer for the additional amount of the protective material. In other words, even more protective material may be dispensed without overflowing into the region V1 and/or the side surface 204 of the component 20.

FIG. 1C is a cross-section of a semiconductor device package (e.g., the semiconductor device package 1) in accordance with some embodiments of the present disclosure. The component 20 may be configured for external communication. The component 20 of the semiconductor device package 1 may include at least one coupler 20w to be coupled to an optical fiber 100. The coupler 20w may has a first end coupled with a waveguide of the component 20 (not shown) and has a second end coupled with the optical fiber 100. The coupler 20w may include a condenser lens, collimating lens, or filtering lens. In some embodiments, the coupler 20w may be a terminal of the waveguide of the component 20. The side surface 204 may be configured to for optically coupling. The connection of the coupler 20w and the optical fiber 100 may include edge coupling. In some embodiments, the connection of the coupler 20w and the optical fiber 100 may include grating coupling. The optical fiber 100 may have a coupling end 100c optically coupled with the component 20 through the side surface 204. The coupler 20w may be configured to couple to the optical fiber 100 (or the coupling end 100c). The coupler 20w at the side surface 204 may overlap the region B1 in the direction DR3. The coupler 20w may be adjacent to the side surface 104. The coupler 20w may be configured to transceive an external signal. The coupler 20w may be configured to transmit optical signals between the optical fiber 100 and the component 20. The optical fiber 100 may be connected or attached to the side surface 204 by an adhesive material (or a second protective element) 150. The protective element 150 may encapsulate the coupling end 100c of the optical fiber 100. The adhesive material 150 may include epoxy. The adhesive material 150 may have a coefficient of thermal expansion different from that of the protective element 40.

Owing to the protective element 40 (or the portion 401) being spaced apart from the side surface 204 of the component 20, the protective element 40 may not adversely affect the connection of the optical fiber 100 and the coupler 20w at the side surface 204 of the component 20. Furthermore, the protective element 40 may be free from contact with the adhesive material (or the protective element) 150. This prevents any possible peeling defects between the protective element 40 and the adhesive material 150. Therefore, the reliability of the semiconductor device package 1 can be increased.

In some comparative embodiments, a plurality of interconnection elements may be evenly distributed under a photonic IC (PIC) for providing electrical connection between the PIC and a carrier. The outermost interconnection elements may be disposed adjacent the edge of the PIC. An encapsulant may be formed between the PIC and the carrier to protect the interconnection elements. However, during the formation of the encapsulant, a portion of a filling material may overflow to the edge of the PIC and hinder the connection between a coupler at the edge of the PIC and an optical fiber. Furthermore, an adhesive material adhering the optical fiber to the PIC may cover the encapsulant which has coefficient of thermal expansion different from that of the adhesive material. The adhesive material may be peeled from the encapsulant. The peeling defects may deteriorate the optical coupling efficiency.

In the present disclosure, the interconnection elements 70 are limited in the region A1. No interconnection elements are located in the region B1 (i.e., the clearance region of interconnection elements). The region B1 with the relatively long length L1 provides a buffer zone for the overflow of a protective material during the formation of the protective element 40. As such, the portion (or the overhang portion) 20h and the side surface 204 of the component 20 may not contact the protective element 40. Owing to the protective element 40 being spaced apart from the side surface 204 of the component 20, the protective element 40 may not adversely affect the connection of the optical fiber 100 and the coupler 20w at the side surface 204 of the component 20. The region B1 allows for more buffer for the additional amount of protective material. In other words, even more protective material may be dispensed without overflowing into the region V1 and/or the side surface 204 of the component 20. Furthermore, the protective element 40 may be free from contact with the adhesive material 150. This prevents any possible peeling defects between the protective element 40 and the adhesive material 150. Therefore, the reliability of the semiconductor device package 1 can be increased. In some embodiments, the semiconductor device package 1 may further include a component 60 stacked over the component 20. In some embodiments, the protective element 40 may be free from contact with the component 60. In some embodiments, the component 60 includes an electronic component, such as an EIC. In some embodiments, the component 60 includes a DSP, a TIA, a DRV, or a combination thereof.

In some embodiments, the semiconductor device package 1 may further include a plurality of interconnection elements 92 between the component 20 and the component 60. The interconnection elements 92 may be or include conductive pads, conductive studs, conductive bumps, UBMs, or a combination thereof. In some embodiments, the semiconductor device package 1 may further include a protective element 94 covering or encapsulating the interconnection elements 92. In some embodiments, the protective element 40 may be free from contact with the protective element 94. In some embodiments, the protective element 94 may be free from contact with the conductive pads 210. The protective element 94 may be or include an encapsulant. The protective element 94 may include an epoxy resin having fillers, a molding compound (e.g., an epoxy molding compound or other molding compound), polyimide, a phenolic compound or material, a material with a silicone dispersed therein, or a combination thereof.

The component 20 may include a plurality of conductive vias 20v extending between the surface 201 and the surface 202. The conductive vias 20v may be electrically connected to the interconnection elements 92. The conductive vias 20v may be electrically connected to the interconnection elements 70. The component 20 may be electrically connected to the carrier 10 through the interconnection elements 92, conductive vias 20v, and interconnection elements 70.

In some embodiments, the component 20 may include a plurality of conductive traces (not shown) at the surface 201 and the surface 202 electrically connected to the conductive vias 20v. The conductive traces may be a redistribution layer for connecting the interconnection elements 92 and the conductive vias 20v or the interconnection elements 70 and the conductive vias 20v.

According to some embodiments of the present disclosure, with the design of the protective element 40 free from contact with the protective element 94, peeling between the protective element 40 and the protective element 94 resulting from contact between different encapsulant materials can be prevented. Therefore, the reliability of the semiconductor device package 1 can be increased.

FIG. 1C-1 is a cross-section of a semiconductor device package in accordance with some embodiments of the present disclosure. (e.g., the semiconductor device package 1). FIG. 1C-1 illustrates a scenario that during the formation of the protective element 40, an excess amount of a protective material may overflow into the region B1 and region V1 to form a portion 409. The portion 409 may be in contact with the portion 202V of the lower surface 202 of the component 20. The portion 409 may have an end 409e in contact with the portion 202V of the lower surface 202 of the component 20. The portion 409 may not be in contact with the side surface 204 of the component 20.

The protective element 150 may cover the end 409e of the portion 409 of the protective element 40. In order to prevent any possible peeling defects between the protective element 40 and the protective element 150, the protective element 40 and the protective element 150 may have the same or similar material base. Thus, the adhesive material 150 may have a coefficient of thermal expansion the same as or similar to that of the protective element 40.

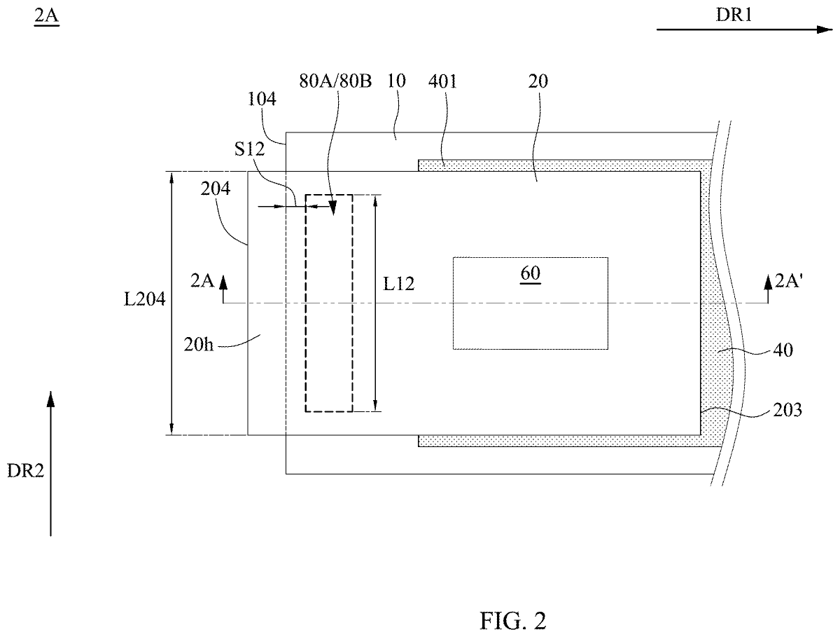

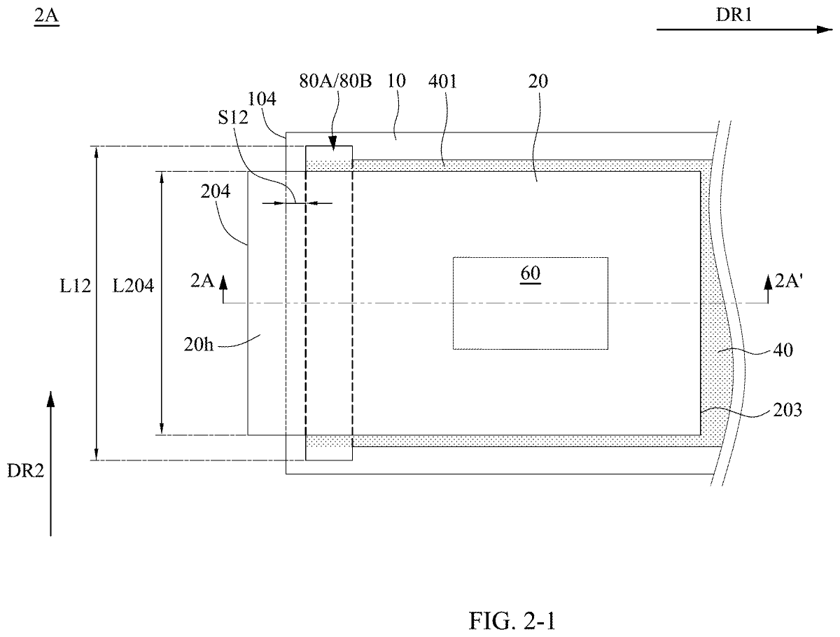

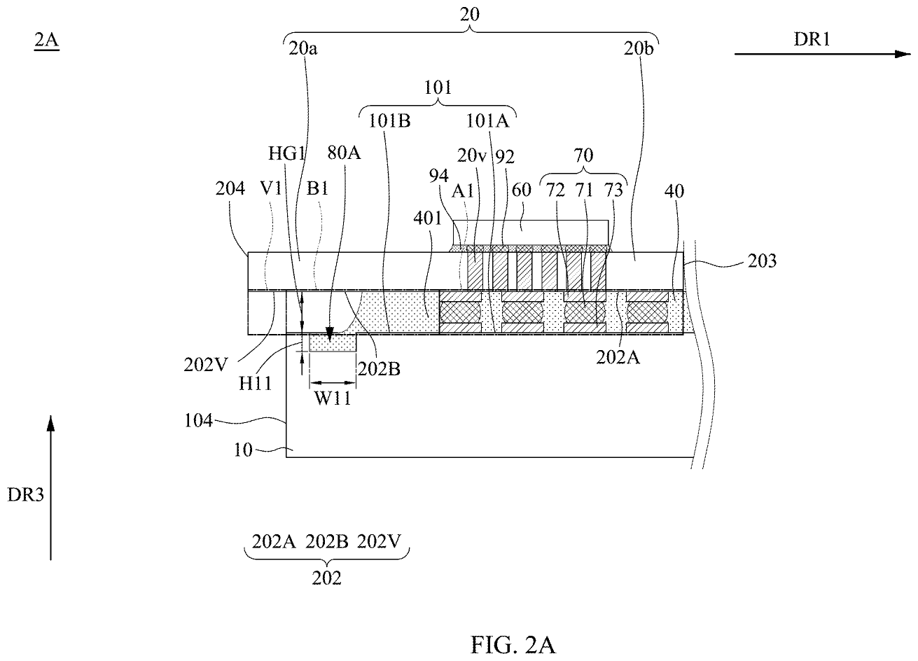

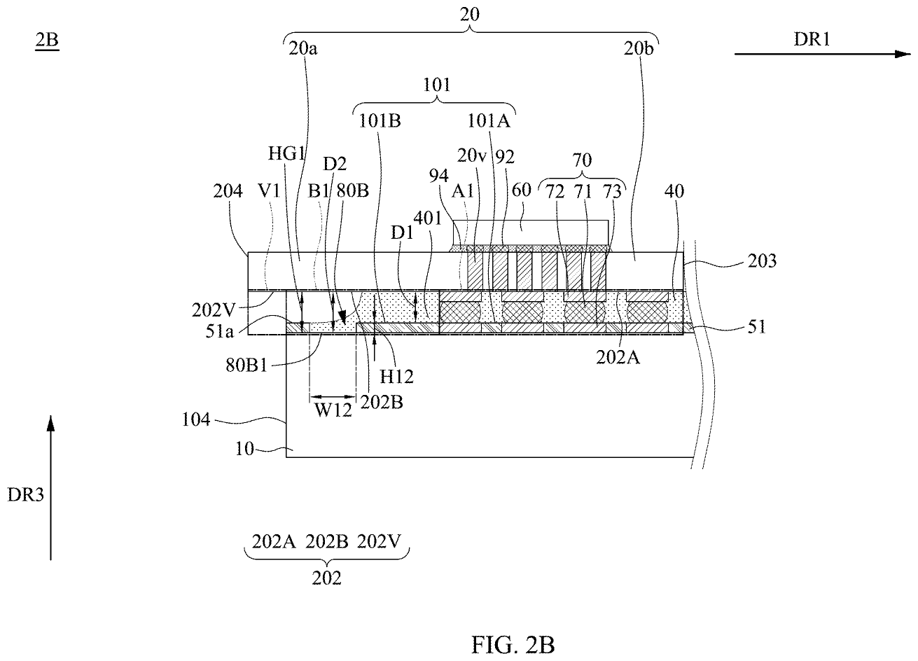

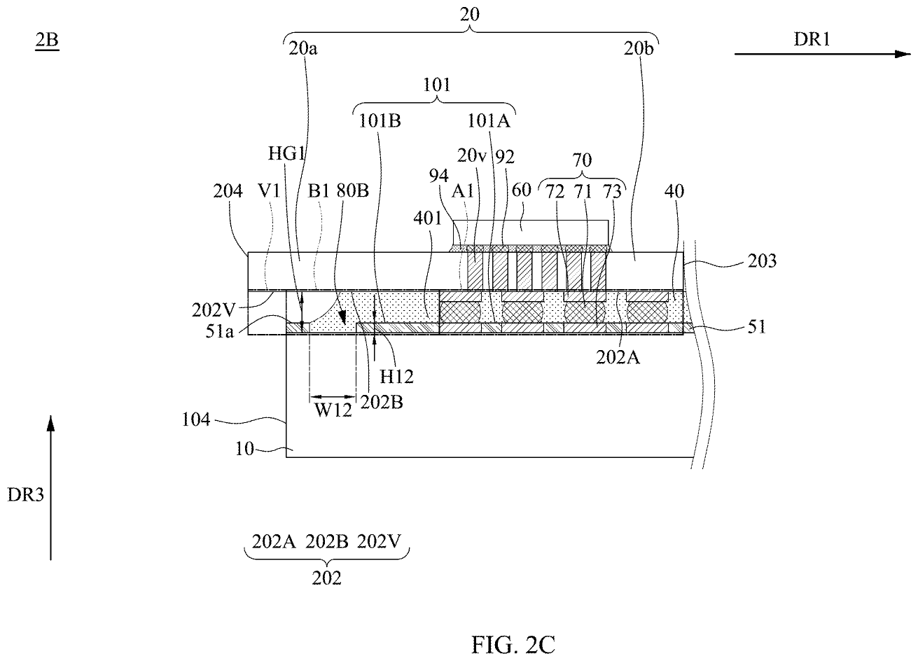

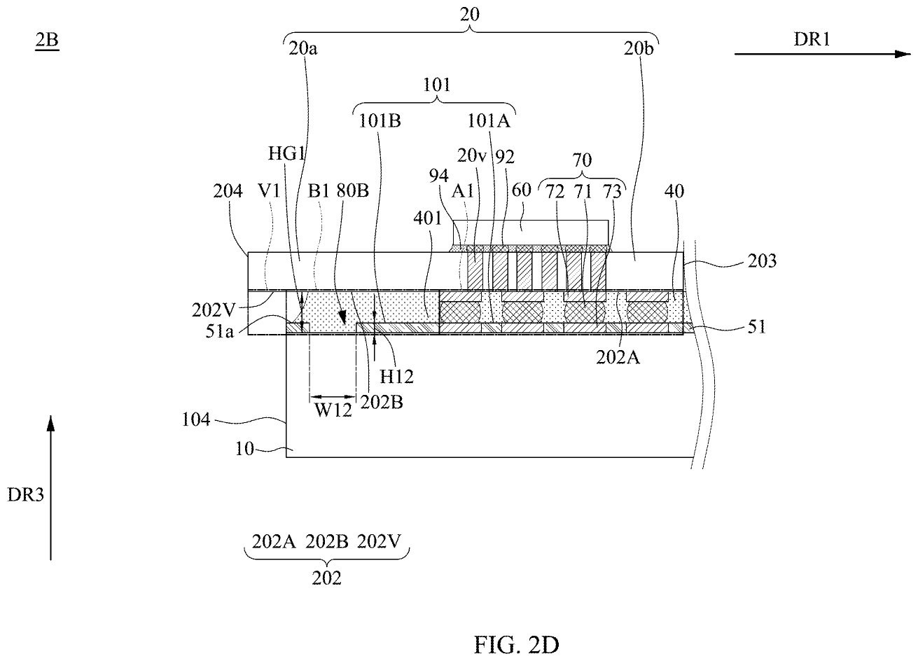

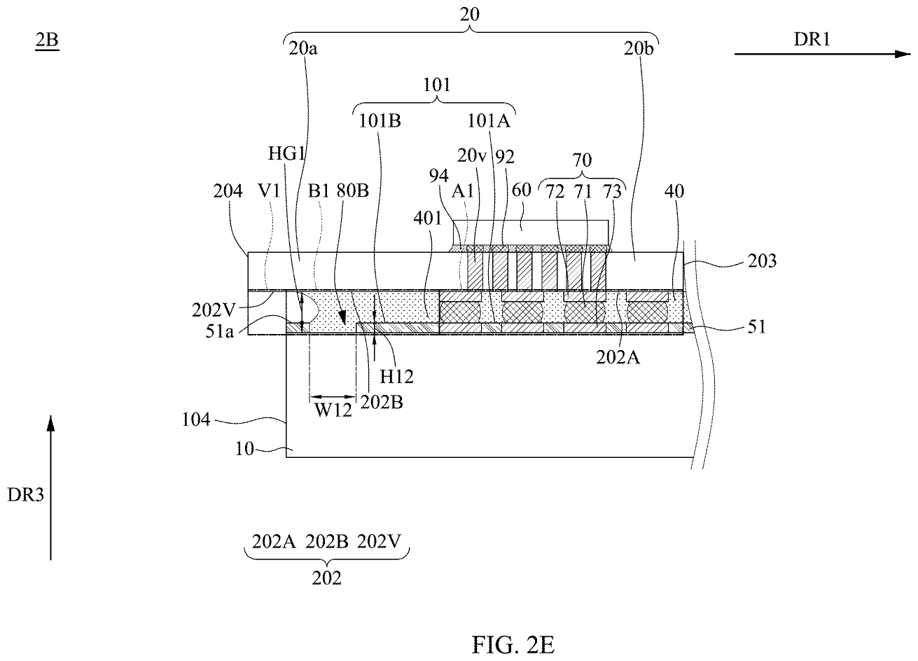

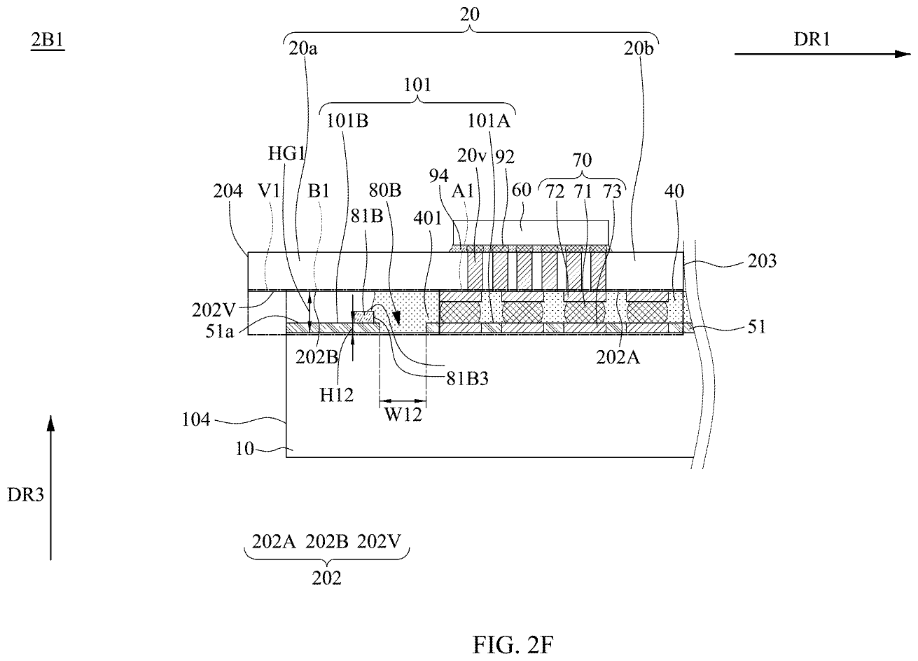

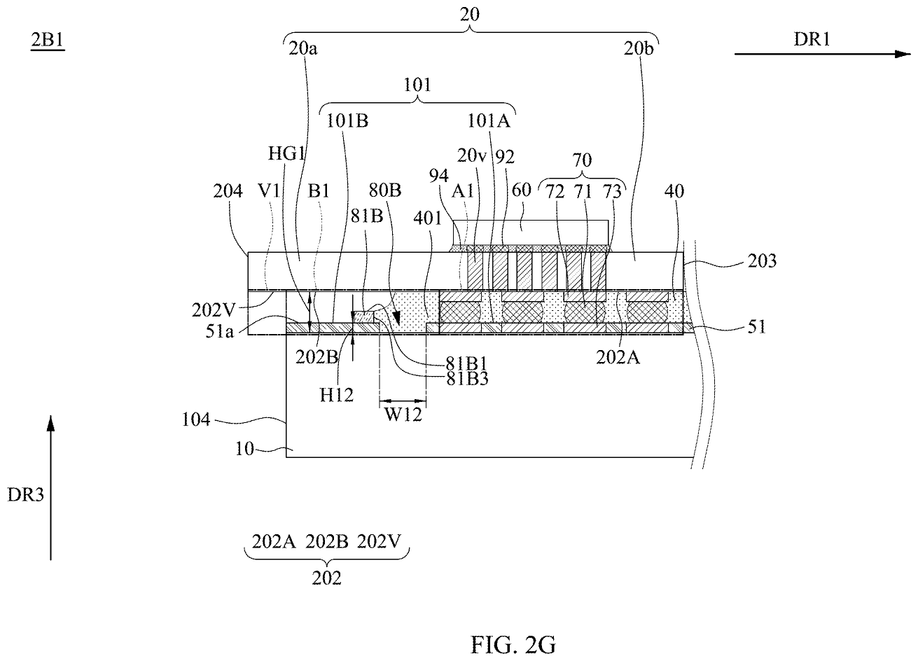

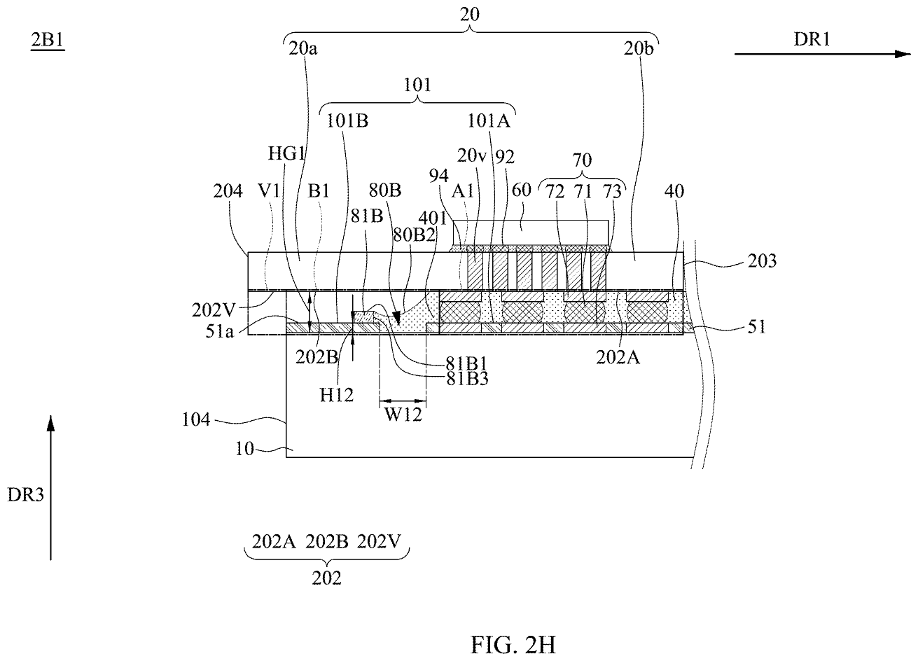

FIG. 1C-2 is a cross-section of a semiconductor device package (e.g., the semiconductor device package 1) in accordance with some embodiments of the present disclosure. FIG. 1C-2 illustrates a scenario that during the formation of the protective element 40, an excess amount of a protective material may overflow into the region B1 and region V1 to form a portion 410. The portion 410 may be in contact with the portion 202V of the lower surface 202 of the component 20. The portion 410 may have an end 410e in contact with the side surface 204 of the component 20. The end 410e may only reach the lower part of the side surface 204 of the component 20; that is, the end 410e may not cover the coupler 20w at the side surface 204.

The protective element 150 may cover the end 410e of the portion 410 of the protective element 40. In order to prevent any possible peeling defects between the protective element 40 and the protective element 150, the protective element 40 and the protective element 150 may have the same or similar material base. Thus, the adhesive material 150 may have a coefficient of thermal expansion the same as or similar to that of the protective element 40.

FIG. 1D is a top view of a portion of a semiconductor device package (e.g., the semiconductor device package 1) in accordance with some embodiments of the present disclosure. FIG. 1D illustrates the component 20, the conductive elements 70, and the protective element 40, and omits other components as illustrated in FIGS. 1 and 1A for the demonstration of the relationship of the conductive elements and the regions A1, B1, and V1.

The component 20 and the carrier 10 may further define at least one region A3 distinct from the region A1 and the region B1. The region A3 may be defined by a portion 202C of the surface 202 of the component 20 and a corresponding portion of the surface 101 (not shown) of the carrier 10. The at least one region A3 may be next to the region B1. The at least one region A3 may be connected to the region B1. The at least one region A3 may be connected between the region A1 and the region B1. The at least one region A3 surrounds the region B1. The at least one region A3 may have a region adjacent to a side of the region B1 and another region adjacent to an opposite side of the region B1. The region A3 may be adjacent to the region A1 at a first side and adjacent to the region B1 at a second, different, side. A side Bla of the region B1 facing the side surface 204 of the component 20 may be aligned with a side A3a of the region A3 facing the side surface 204. The at least one region A3 may be between the region V1 and the region A1. Referring to FIG. 1C, the coupler 20w may be adjacent to the side surface 104 and over the region B1.

The semiconductor device package 1 may include a supporting structure (or a supporting element) 75 disposed in the at least one region A3. The region A3 may be configured to accommodate the supporting structure 75 between the component 20 and the carrier 10. The supporting structure 75 in the at least one region A3 may be configured to support the component 20. The supporting structure 75 may be configured to prevent the component 20 from warping. In some embodiments, a portion of the component 20 having the surface 202A and the overhang portion 20h may be dangling since no supporting element is provided therebelow. The supporting structure 75 may be configured to prevent the component 20 from dangling. The supporting structure 75 may reduce the warpage of the component 20 to an acceptable level, e.g., between +8 μm and +2 μm, between −8 μm and −2 μm, or less than +/−2 μm.

The supporting structure 75 may be a plurality of interconnection elements (symbol 75 hereafter). The plurality of interconnection elements 75 may have a pitch P2. The plurality of interconnection elements 70 may have a pitch P1. In some embodiments, the pitch P1 and the pitch P2 may be substantially the same. In some embodiments, the pitch P1 and the pitch P2 may be different. The pitch P2 may be relatively large to leave a room for accommodating the overflow of the protective material (e.g., the portion 402). Alternatively, the pitch P1 may be relatively small to enhance the capillary effect to attract the overflow of the protective material (corresponding the portions 401), such that the portion 401 in the region B1 can be smaller.

The plurality of interconnection elements 70 and 75 may be formed in the same process. The plurality of interconnection elements 75 may be similar to the plurality of interconnection elements 70. In some embodiments, the plurality of interconnection elements 75 may be electrically isolated from the component 20 and/or the carrier 10. The supporting structure 75 may be electrically disconnected to the component 20. The plurality of interconnection elements 75 may include dummy interconnection elements or at least a dummy bump for supporting the component 20.

The region A1 and the region A3 may be respectively nominated as a first sub-region and a second sub-region of a region defined by overlapping between the carrier 10 and the component 20, wherein the region includes interconnection elements (70 and 75). The interconnection elements 70 formed in the first sub-region A1 may be electrically functional (i.e., transmit an electrical signal between the component 20 and the carrier 10) and the interconnection elements 75 formed in the first sub-region A3 may be configured to support the component 20.

The protective element 40 may include a portion 402 disposed in the region A3. The portion 402 of the protective element 40 may encapsulate a group of the interconnection elements 75, which is close to the interconnection elements 70. The portion 402 may not encapsulate other interconnection elements 75. The portion 402 of the protective element 40 may have an end 402e between two interconnection elements 75. The portion 402 and the portion 401 of the protective element 40 may be continuous. The portion 402 and the portion 401 may have a round shape from the top view.

FIG. 1D-1 is a top view of a portion of a semiconductor device package (e.g., the semiconductor device package 1) in accordance with some embodiments of the present disclosure. FIG. 1D illustrates the component 20, the conductive elements 70, and the protective element 40, and omits other components as illustrated in FIGS. 1 and 1A for the demonstration of the relationship of the conductive elements and the regions A1, B1, and V1. FIG. 1D-1 illustrates that the portion 402′ fully covers the interconnection elements 75. The end 402e′ of the portion 402′ may be between the side surface 204 and the interconnection element 75 being closest to the side surface 204. The portion 402′ and the portion 401 of the protective element 40 may be continuous. The portion 402′ and the portion 401 may have a round shape from the top view.

FIG. 1E is a cross-section of a semiconductor device package 1A the in accordance with some embodiments of the present disclosure. In some embodiments, FIG. 1E is a cross-section along line 1E-1E′ in FIG. 1D. As shown in FIG. 1E, the portion 402 may encapsulate one of the interconnection elements 75. The end 402e of the portion may be between two interconnection elements 75. The portion 402 may not encapsulate or cover all of the interconnection elements 75.

FIG. 1F is a top view of a portion of a semiconductor device package (e.g., the semiconductor device package 1) in accordance with some embodiments of the present disclosure. FIG. 1F illustrates the component 20 and the conductive elements 70 and omits other components as illustrated in FIGS. 1 and 1A for the demonstration of the relationship of the conductive elements and the regions A1, B1, V1, and A3. The embodiments of FIG. 1F are similar to those of FIG. 1D, except that the semiconductor device package 1 may further include a supporting element 77 disposed in the at least one region A3. The supporting structure 77 may be configured to prevent the component 20 from warping. In some embodiments, a portion of the component 20 having the surface 202A and the overhang portion 20h may be dangling since no supporting element is provided therebelow. The supporting structure 77 may be configured to prevent the component 20 from dangling. The supporting structure 77 may reduce the warpage of the component 20 to an acceptable level, e.g., +/−1 μm.

The supporting structure 77 may include a semiconductor die (symbol 77 hereafter) having the same height as the interconnection elements 70. The semiconductor die 77 may be electrically isolated from the component 20 and/or the carrier 10. The semiconductor die 77 may be attached to the carrier 10 and/or the component 20 via an adhesive layer (not shown). The semiconductor die 77 may be at least a dummy die. The semiconductor die 77 may be attached to the carrier10 and/or the component 20 via a plurality of bumps.

The protective element 40 may include a portion 403 disposed in the region A3. The portion 403 of the protective element 40 may partially encapsulate the semiconductor die 77. The portion 403 of the protective element 40 may have an end 403e at the middle part of the semiconductor die 77. The portion 403 and the portion 401 of the protective element 40 may be continuous. The portion 403 and the portion 401 may have a round shape from the top view.

FIG. 1G is a top view of a portion of a semiconductor device package in accordance with some embodiments of the present disclosure. As shown in FIG. 1G, a region A3′ may be surrounded by at least one region B1′. A support structure 77′ may be disposed in the region A3′ to support the component 20. The support structure 77′ may include a semiconductor die.

FIG. 1H is a cross-section of a semiconductor device package 1B in accordance with some embodiments of the present disclosure. The semiconductor device package 1B of FIG. 1H is similar to the semiconductor device package 1 of FIG. 1A, except that a portion 401′ of the protective element 40 of the semiconductor device package 1B may have an end 401e′ closer to the region V1 than the region A1. The portion 401′ may be closer to the side surface 204 of the component 20 than the interconnection elements 70. The portion 401′ may be closer to the turning point P102 than the point P101. The semiconductor device package 1A may correspond to a case in which an additional amount of a protective material has been applied to the gap between the component 20 and the carrier 10 during the formation of the protective element 40. The region B1 allows for more buffer for the additional amount of protective material. In other words, even more protective material may be dispensed without overflowing into the region V1 and/or the side surface 204 of the component 20.

A region C1 distinct from the region A1 and B1 may be defined by the lower surface 202 of the component 20 and the upper surface 101 of the carrier 10. The region C1 may accommodate none of any portion of the protective element and none of the plurality of interconnection elements.

FIG. 1I is a cross-section of a semiconductor device package 1C in accordance with some embodiments of the present disclosure. The semiconductor device package 1C of FIG. 1I is similar to the semiconductor device package 1B of FIG. 1H, except that the end 401e′ of the portion 401′ of the protective element 40 of the semiconductor device package 1C may reach the side surface 104 of the turning point P102. The portion 401′ may not reach the region V1 or the portion 202V of the surface 202 of the component 20.

FIG. 2 is a top view of a semiconductor device package 2A in accordance with some embodiments of the present disclosure. FIG. 2-1 is a top view of the semiconductor device package in accordance with some embodiments of the present disclosure. FIG. 2A is a cross-section of the semiconductor device package 2A in accordance with some embodiments of the present disclosure. In some embodiments, FIG. 2A is a cross-section along line 2A-2A′ in FIG. 2. In some embodiments, the semiconductor device package 2A of FIGS. 2 and 2A is similar to the semiconductor device package 1 of FIGS. 1 and 1A. Some details may correspond to previous descriptions and are thus not repeated for brevity, with differences discussed as follows.

The semiconductor device package 2A may include a blocking structure 80A. As shown in FIG. 2, the blocking structure 80A may have a length L12 in the direction DR2 and the component 20 may have a length L204 in the direction DR2. The length L204 of the component 20 may be greater than the length L12 of the blocking structure 80A. The blocking structure 80A may be spaced apart from the side surface 104 of the carrier 10 with a spacing S12. The spacing S12 may be in a range from around 100 μm to around 200 μm. As shown in FIG. 2-1, the length of the component 20 may be shorter than the length of the blocking structure 80A.

In some embodiments, the blocking structure 80A is recessed from the surface 101 (or the portion 101B) of the carrier 10. In some embodiments, the blocking structure 80A may be or include a trench recessed from the portion 101B of the surface 101 of the carrier 10. In some embodiments, a portion of the portion 401 of the protective element 40 may be filled in the trench (i.e., the blocking structure 80A). In some embodiments, the blocking structure 80A may be in contact with the portion 401 of the protective element 40. In some embodiments, the blocking structure 80A has a depth H11 (or height) less than the height HG1 between the component 20 and the carrier 10. The blocking structure 80A may have a width W11 in the direction DR1. The depth H11 of the blocking structure 80A may be in a range from around 20 μm to around 30 μm. The width W11 of the blocking structure 80A may be in a range from around 50 μm to around 200 μm.

According to some embodiments of the present disclosure, the blocking structure 80A can prevent the material of the protective element 40 (e.g., a protective material) from overflowing into the region V1 during manufacture of the semiconductor device package 2A. The excess material may flow and fill in the trench of the blocking structure 80A, and thus the region V1, the side surface 104 of the carrier 10, and/or the side surface 204 of the component 20 can be free from contact with (or touching) the protective element 40. In other words, the blocking structure 80A may prevent the protective element 40 from approaching the side surface 204 of the component 20. Therefore, the optical coupling efficiency of the semiconductor device package 2A and an external device (e.g., the optical fiber 100 of FIG. 1C) can be increased. The yield of the semiconductor device package 2A can be improved.

FIG. 2B is a cross-section of a semiconductor device package 2B in accordance with some embodiments of the present disclosure. The semiconductor device package 2B is similar to the semiconductor device package 2A in FIG. 2A, with differences therebetween as follows.

In some embodiments, the semiconductor device package 2B may include a blocking structure 80B, rather than the blocking structure 80A. In some embodiments, the carrier 10 includes a solder resist layer 51 at the surface 101 of the carrier 10. In some embodiments, the blocking structure 80B may be recessed from an upper surface 51a of the solder resist layer 51. The upper surface 51a may face the surface 202 of the component 20. The upper surface 51a may be referred as the upper surface 10 of the carrier 10. In some embodiments, the blocking structure 80B may be or include a trench recessed from the upper surface 51a of the solder resist layer 51. In some embodiments, the solder resist layer 51 may define the blocking structure 80B.

The blocking structure 80B may define a blocking structure region between the upper surface 101 of the carrier 10 and the lower surface 202 of the component 20. A first distance D1 between the upper surface 51a of the solder resist layer 51 (also referred as the upper surface 101 of the carrier 10) and the lower surface 202 of the component 20 in a region other than the blocking structure region may be different from a second distance D2 between a surface (or a bottom surface) 80B1 of the blocking structure region and the lower surface 202 of the component 20 in the blocking structure region. The second distance D2 may be greater than the first distance D1. In other words, the surface 80B1 of the blocking structure region may be at an elevation different from that of the upper surface 101 of the carrier. The surface 80B1 of the blocking structure region may be lower than the upper surface 101 of the carrier 10. The surface 80B1 of the blocking structure region may be recessed from the upper surface 51a of the solder resist layer 51.

In some embodiments, a portion of the portion 401 of the protective element 40 may be filled in the trench (i.e., the blocking structure 80B). In some embodiments, the blocking structure 80B be in contact with the portion 401 of the protective element 40. In some embodiments, the blocking structure 80B has a depth H12 (or height) less than the height HG1 between the component 20 and the carrier 10. The depth H12 of the blocking structure 80B substantially equals to the thickness of the solder resist layer 51. The blocking structure 80B may have a width W12 in the direction DR1. The depth H12 of the blocking structure 80B may be in a range from around 20 μm to around 30 μm. The width W12 of the blocking structure 80B may be in a range from around 50 μm to around 200 μm. The width W12 may be greater than the depth D12. FIG. 2 may illustrate a top view similar to that of the semiconductor device package 2B. For example, the length of the blocking structure 80B may be longer or shorter than the length of the component 20.

According to some embodiments of the present disclosure, the blocking structure 80B can prevent the material of the protective element 40 (e.g., a protective material) from overflowing into the region V1 during manufacture of the semiconductor device package. The excess material may flow and fill in the trench of the blocking structure 80B defined by the solder resist layer 51, and thus the region V1 and the side surface 204 of the component 20 can be free from contact with the protective element 40. In other words, the blocking structure 80B may prevent the protective element 40 from approaching the side surface 204 of the component 20. Therefore, the optical coupling efficiency of the semiconductor device package 2B and an external device (e.g., the optical fiber 100 of FIG. 1C) can be increased. The yield of the semiconductor device package 2B can be improved.

FIG. 2C, 2D, 2E, 2F, 2G, 2H is a cross-section of a semiconductor device package in different scenarios in which the amount of the protective material during the formation of the protective element 40 (including the portion 401) is varied.

As shown in FIG. 2C, the portion 401 may be partially disposed in the blocking structure 80B and the majority of the portion 401 may be outside of the blocking structure 80B.

As shown in FIG. 2D, the portion 401 may be partially disposed in the blocking structure 80B. The portion 401 may be disposed over the surface 51a of the solder resist layer 51.

As shown in FIG. 2E, the portion 401 may be partially disposed in the blocking structure 80B. The portion 401 may extend on the lower surface 202 of the component 20 in a greater extent than on the surface 51a of the solder resist layer 51 because of the stronger adhesion force between the portion 401 and the lower surface 202. The portion 401 may extend beyond the blocking structure region owing to the capillary effect. The portion 401 may have a concave shape.

As shown in FIG. 2F, a blocking structure 81B may disposed over the surface 51a of the solder resist layer 51. The blocking structure 81B may be disposed in the region B1. The blocking structure 80B may be disposed between the blocking structure 81B and the interconnection elements 70. The blocking structure 81B may be configured to prevent the portion 401 from reaching the region V1 or the side surface 204 of the component 20. The portion 401 may be in contact with a lateral surface 81B3 and a top surface 81B1 of the blocking structure 81B. The blocking structure 81B may include a dam or wall extending substantially parallel with the blocking structure 80B. The blocking structure 81B may define a blocking structure region between the upper surface 101 of the carrier 10 and the lower surface 202 of the component 20. The top surface 81B1 of the blocking structure region may be at an elevation different from that of the upper surface 101 of the carrier. The surface 81B1 of the blocking structure region may be higher than the upper surface 101 of the carrier 10.

As shown in FIG. 2G, the portion 401 may only reach the lateral surface 81B3 of the blocking structure 81B and be not in contact with the upper surface 81B1 of the blocking structure 81B. The portion 401 may partially disposed in the blocking structure 80B.

As shown in FIG. 2H, the portion 401 may only reach the lateral surface 81B3 of the blocking structure 81B and be not in contact with the upper surface 81B1 of the blocking structure 81B. The portion 401 may partially disposed in the blocking structure 80B. The portion 401 may have a concave surface 80B2 facing the lower surface 202 of the component 20. The upper surface 81B1 of the blocking structure 81B may be higher than the lowest point of the concave surface 80B2 of the portion 401.

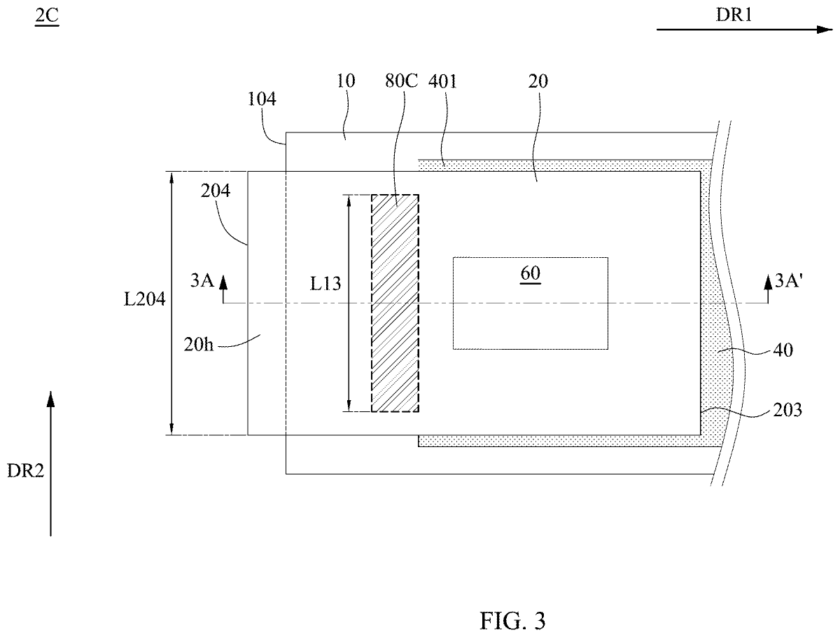

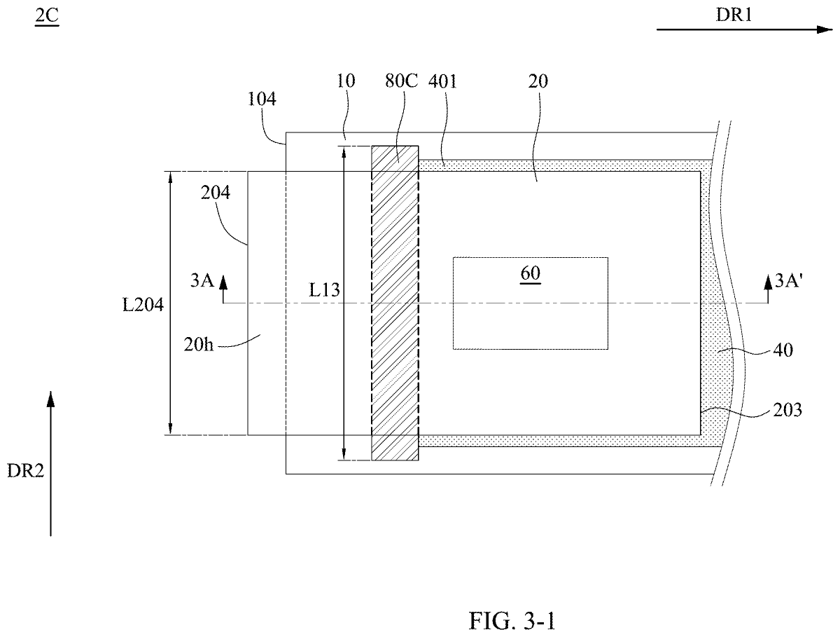

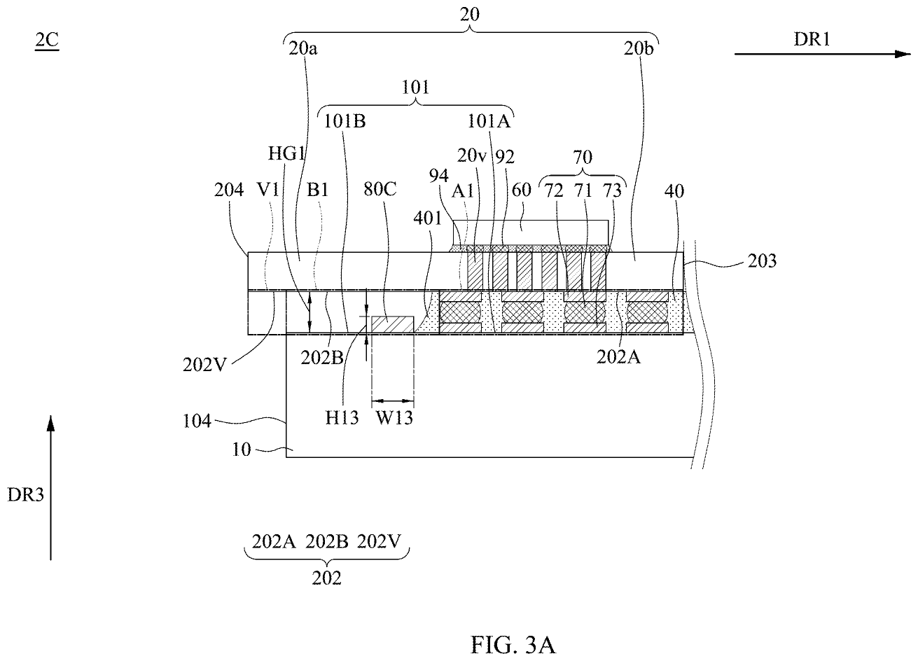

FIG. 3 is a top view of a semiconductor device package 2C in accordance with some embodiments of the present disclosure. FIG. 3-1 is a top view of the semiconductor device package 2C in accordance with some embodiments of the present disclosure. FIG. 3A is a cross-section of the semiconductor device package 2C in accordance with some embodiments of the present disclosure. In some embodiments, FIG. 2C is a cross-section along line 3A-3A′ in FIG. 3. In some embodiments, the semiconductor device package 2C of FIGS. 3 and 3A is similar to the semiconductor device package 1 of FIGS. 1 and 1A. Some details may correspond to previous descriptions and are thus not repeated for brevity, with differences discussed as follows.

The semiconductor device package 2C may include a blocking structure 80C. As shown in FIG. 2, the blocking structure 80C may have a length L13 in the direction DR2 and the component 20 may have a length L204 in the direction DR2. The length L204 of the component 20 may be greater than the length L13 of the blocking structure 80C. As shown in FIG. 3-1, the length of the component 20 may be shorter than the length of the blocking structure 80C.

The blocking structure 80C may be disposed on the portion 101B of the surface 101 of the carrier 10. The blocking structure 80C may be in contact with the portion 101B of the surface 101 of the carrier 10. The blocking structure 80C may be in the region B1. In some embodiments, the blocking structure 80C may include a wall structure. In some embodiments, the blocking structure 80C may include a protrusion. In some embodiments, the blocking structure 80C may be in contact with the portion 401 of the protective element 40. In some embodiments, the blocking structure 80C has a thickness H13 (or height) less than the height HG1 between the component 20 and the carrier 10. The blocking structure 80C may have a width W13 in the direction DR1. The thickness H13 of the blocking structure 80C may be in a range from around 20 μm to around 30 μm. The width W13 of the blocking structure 80C may be in a range from around 100 μm to around 200 μm. In some embodiments, the blocking structure 80C may be electrically isolated or insulated from the interconnection elements 70. The blocking structure 80C may include a solder resist layer.

According to some embodiments of the present disclosure, the blocking structure 80C can prevent the material of the protective element 40 (e.g., a protective material) from overflowing into the region V1 during manufacture of the semiconductor device package 2C. The excess material may flow and be stopped by the wall structure of the blocking structure 80C, and thus the region V1 and/or the side surface 204 of the component 20 can be free from contact with the protective element 40. In other words, the blocking structure 80C may prevent the protective element 40 from approaching the side surface 204 of the component 20. Therefore, the optical coupling efficiency of the semiconductor device package 2C and an external device (e.g., the optical fiber 100 of FIG. 1C) can be increased. The yield of the semiconductor device package 2C can be improved.

In some embodiments, a relatively small gap between an upper surface of the blocking structure 80C and the portion 202B of the surface 202 of the component 20 may magnify the capillary effect and attract the protective material to overflow into the gap. Hence, the size of the blocking structure 80C may be designed to reduce the capillary effect but still be capable of stopping the overflow of the protective material. For example, the width W13 of the blocking structure 80C may be relatively wide while the thickness H13 thereof may be relatively short.

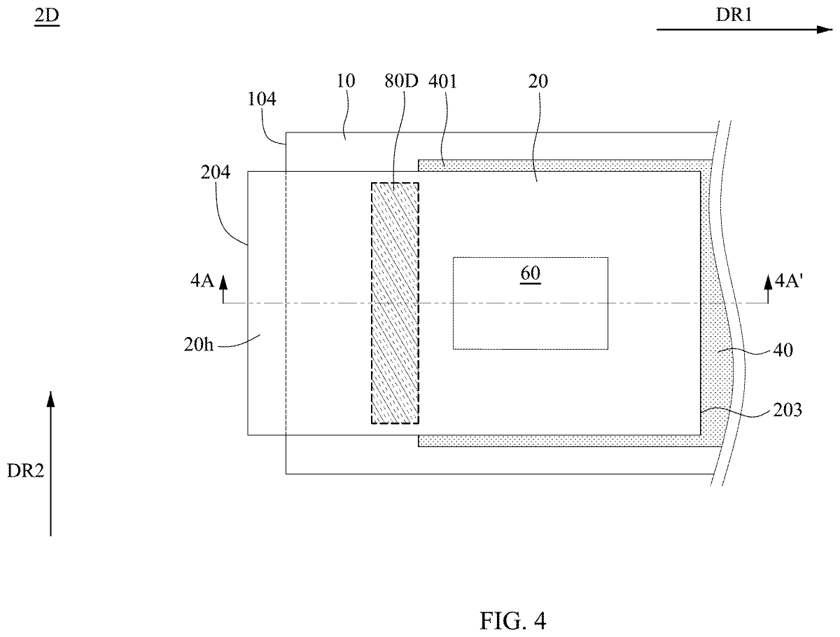

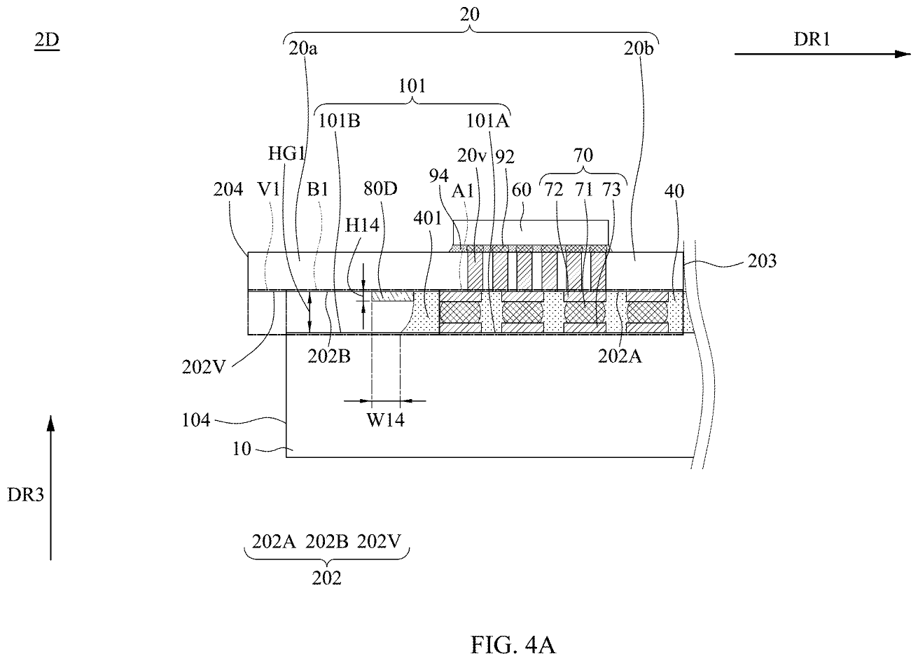

FIG. 4 is a top view of a semiconductor device package 2D in accordance with some embodiments of the present disclosure. FIG. 4A is a cross-section of the semiconductor device package 2D in accordance with some embodiments of the present disclosure. In some embodiments, FIG. 4A is a cross-section along line 4A-4A′ in FIG. 4. In some embodiments, the semiconductor device package 2D of FIGS. 4 and 4A is similar to the semiconductor device package 1 of FIGS. 1 and 1A. Some details may correspond to previous descriptions and are thus not repeated for brevity, with differences discussed as follows.

The semiconductor device package 2D may include a blocking structure 80D. The blocking structure 80D may be disposed below the portion 202B of the surface 202 of the component 20. The blocking structure 80D may be in contact with the portion 202B of the surface 202 of the component 20. The blocking structure 80D may be in the region B1. In some embodiments, the blocking structure 80D may include a wall structure. In some embodiments, the blocking structure 80D may include a protrusion. In some embodiments, the blocking structure 80D may be in contact with the portion 401 of the protective element 40. In some embodiments, the blocking structure 80D may have a thickness H14 (or height) less than the height HG1 between the component 20 and the carrier 10. The blocking structure 80D may have a width W14 in the direction DR1. The thickness H14 of the blocking structure 80D may be in a range from around 5 μm to around 10 μm. The width W14 of the blocking structure 80D may be in a range from around 100 μm to around 200 μm. In some embodiments, the blocking structure 80D may be electrically isolated or insulated from the interconnection elements 70. The blocking structure 80D may include a photoresist of liquid or film type.

According to some embodiments of the present disclosure, the blocking structure 80D can prevent the material of the protective element 40 (e.g., a protective material) from overflowing into the region V1 during manufacture of the semiconductor device package 2D. The excess material may flow and be stopped by the wall structure of the blocking structure 80D, and thus the region V1 and/or the side surface 204 of the component 20 can be free from contact with the protective element 40. In other words, the blocking structure 80D may prevent the protective element 40 from approaching the side surface 204 of the component 20. Therefore, the optical coupling efficiency of the semiconductor device package 2D and an external device (e.g., an external optical fiber 100) can be increased. The yield of the semiconductor device package 2D can be improved.

In some embodiments, a relatively small gap between an upper surface of the blocking structure 80D and the portion 101B of the surface 101 of the carrier 10 may magnify the capillary effect and attract the protective material to overflow into the gap. Hence, the size of the blocking structure 80D may be designed to reduce the capillary effect but still be capable of stopping the overflow of the protective material. For example, the width W14 of the blocking structure 80D may be relatively wide while the thickness H14 thereof may be relatively short.

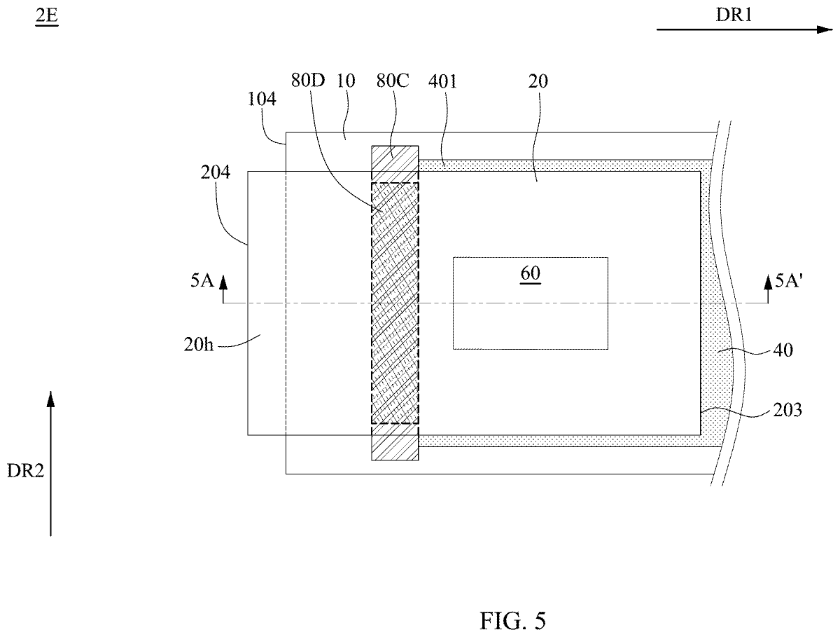

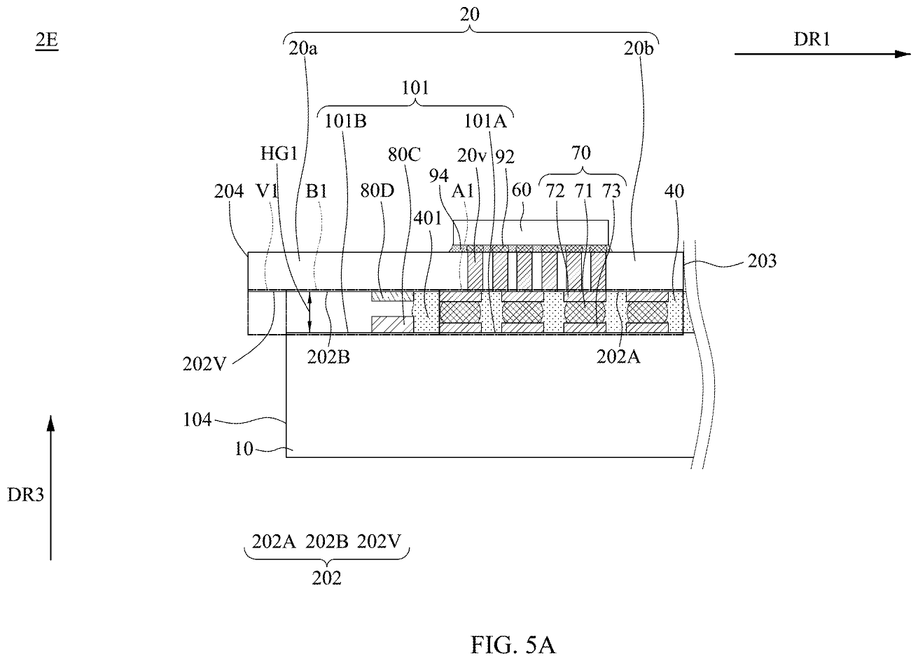

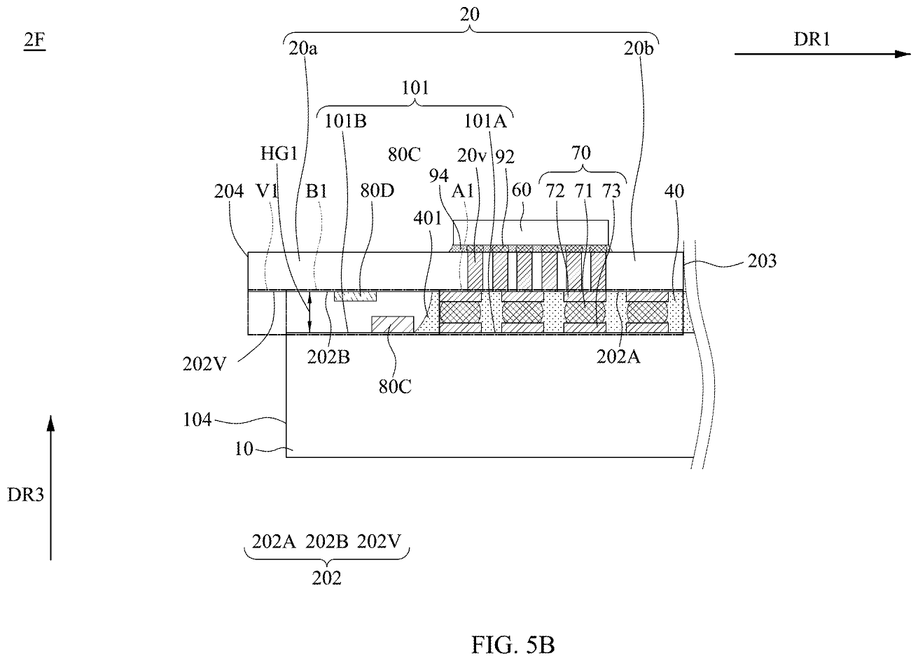

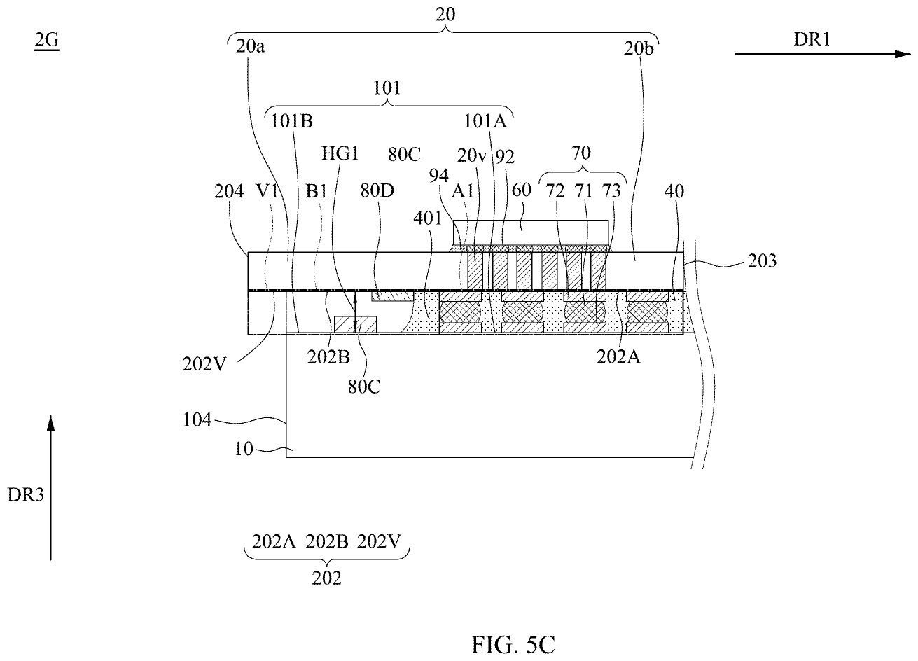

FIG. 5 is a top view of a semiconductor device package 2E in accordance with some embodiments of the present disclosure. FIG. 5A is a cross-section of the semiconductor device package 2E in accordance with some embodiments of the present disclosure. In some embodiments, FIG. 5A is a cross-section along line 5A-5A′ in FIG. 5. In some embodiments, the semiconductor device package 2E of FIGS. 5 and 5A is similar to the semiconductor device package 1 of FIGS. 1 and 1A. Some details may correspond to previous descriptions and are thus not repeated for brevity, with differences discussed as follows.

The semiconductor device package 2E may include a blocking structure 80C and a blocking structure 80D. Detailed descriptions of the blocking structure 80C and the blocking structure 80D refer to the relevant paragraphs of FIGS. 3, 3A, 4, and 4A. The blocking structures 80C and 80D may be disposed in the region B1. The blocking structure 80C may overlap the blocking structure 80D from a top view, as illustrated in FIG. 5. In some embodiments, the blocking structure 80C may be aligned with the blocking structure 80D in the direction DR3.

The blocking structures 80C and 80D may collaboratively prevent the material of the protective element 40 (e.g., a protective material) from overflowing into the region V1 during manufacture of the semiconductor device package 2E. The excess material may flow and be stopped by the wall structure of the blocking structures 80C and 80D, and thus the region V1 and/or the side surface 204 of the component 20 can be free from contact with the protective element 40. Therefore, the optical coupling efficiency of the semiconductor device package 2E and an external device (e.g., an external optical fiber) can be increased. The yield of the semiconductor device package 2E can be improved.

FIG. 5B is a cross-section of a semiconductor device package 2F in accordance with some embodiments of the present disclosure. In some embodiments, the semiconductor device package 2F of FIG. 5B is similar to the semiconductor device package 2E of FIG. 2E. Some details may correspond to previous descriptions and are thus not repeated for brevity, with differences discussed as follows. The blocking structure 80D may be farther away from the region A1 than the blocking structure 80C. The blocking structure 80C may be farther away from the side surface 204 of the component 20 than the blocking structure 80D. In some embodiments, a projecting area of the blocking structure 80D on the surface 101 of the carrier 10 may partially overlap that of the blocking structure 80C. In some embodiments, a projecting area of the blocking structure 80D on the surface 101 of the carrier 10 may be non-overlapping with that the blocking structure 80C.

FIG. 5C is a cross-section of a semiconductor device package 2F in accordance with some embodiments of the present disclosure. In some embodiments, the semiconductor device package 2F of FIG. 5C is similar to the semiconductor device package 2F of FIG. 5C. Some details may correspond to previous descriptions and are thus not repeated for brevity, with differences discussed as follows. The blocking structure 80C may be farther away from the region A1 than the blocking structure 80D. The blocking structure 80C may be closer to the side surface 204 of the component 20 than the blocking structure 80D. In some embodiments, a projecting area of the blocking structure 80D on the surface 101 of the carrier 10 may partially overlap that of the blocking structure 80C. In some embodiments, a projecting area of the blocking structure 80D on the surface 101 of the carrier 10 may be free from overlap with the blocking structure 80C.

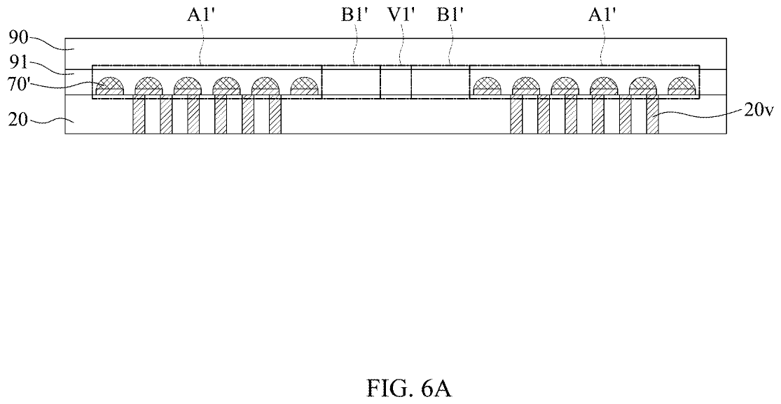

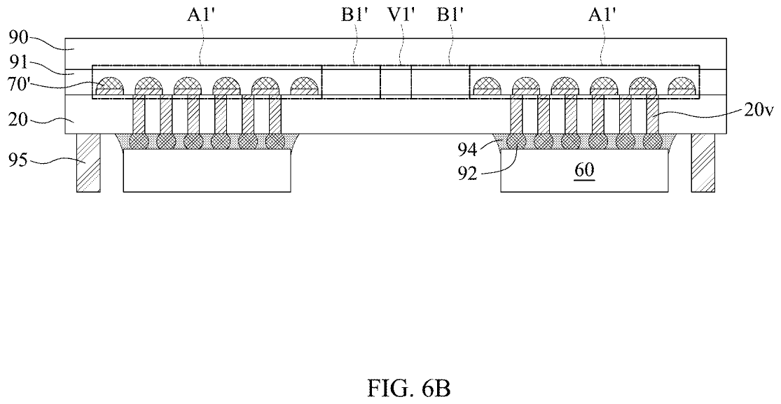

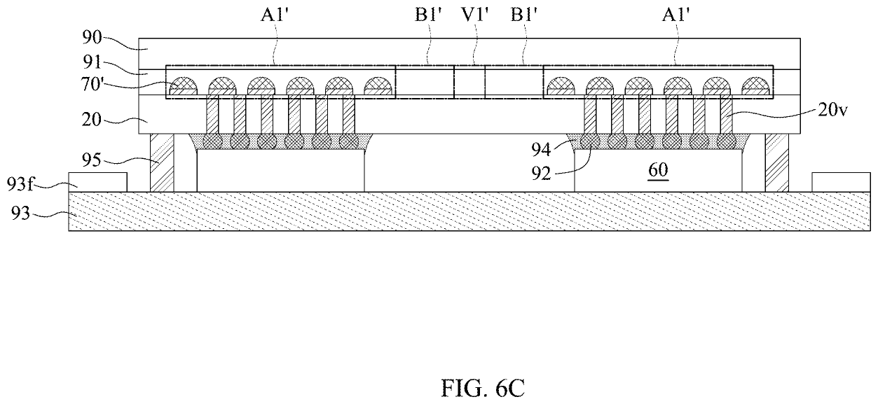

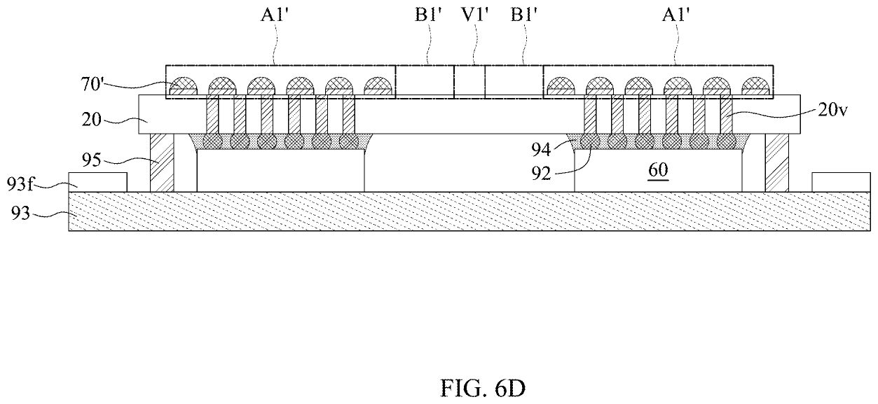

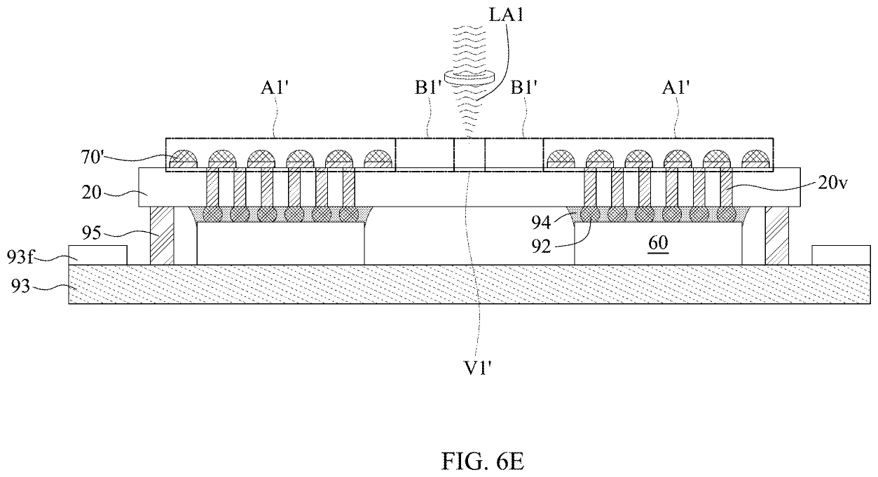

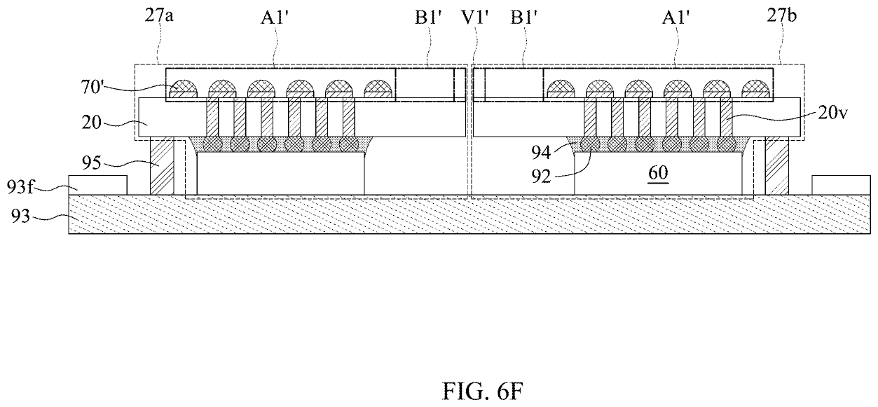

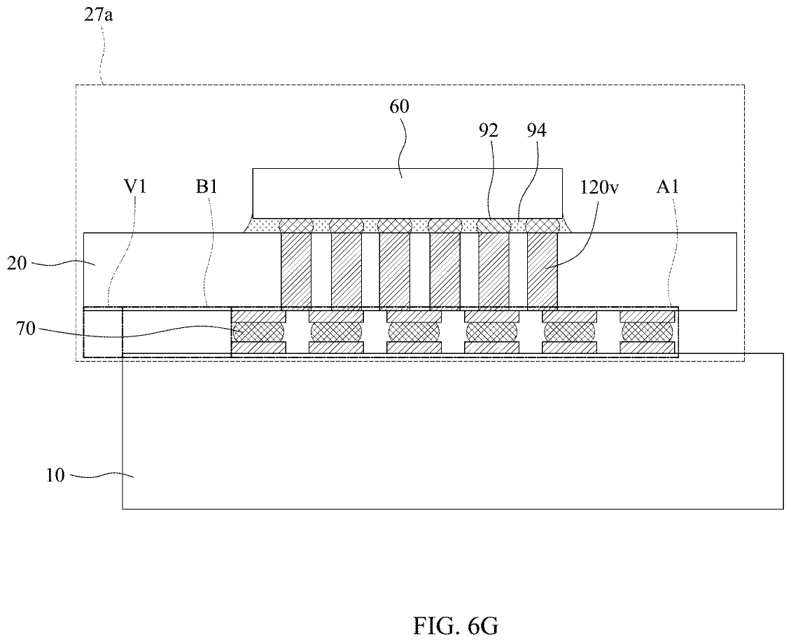

FIGS. 6A, 6B, 6C, 6D, 6E, 6F, and 6G illustrate a method for manufacturing a semiconductor device package according to some embodiments of the present disclosure. In some embodiments, the method is for manufacturing the semiconductor device package 1, 2A, 2B, 2C, 2D, 2E, 2F, or 2G.

Referring to FIG. 6A, a component 20 may be provided with a plurality interconnection elements 70′. The component 20 may be attached to a temporary carrier 90 via an adhesive layer 91. The temporary carrier 90 may include a glass carrier and the adhesive layer 91 may include a glue. The component 20 and the temporary carrier 90 may define a region A1′, where the interconnection elements 70′ are disposed, a region B1′ which is a clearance region of interconnection elements, and a region V1′ between two regions B1′.

Referring to FIG. 6B, a plurality of dummy dies 95 may be attached to the component 20. The dummy dies 95 may be configured to support the component 20. A component 60 may be attached to the component 20 through a plurality of interconnection elements 92. A protective element 94 may cover or encapsulate the interconnection elements 92.

Referring to FIG. 6C, the component 20 may be attached to a dicing tape 93 via the dummy dies 95. The dicing tape 93 may include a frame 93f for securing the dicing tape 93. The component 20 may be surrounded by the frame 93f.

Referring to FIG. 6D, the temporary carrier 90 and the adhesive layer 91 may be removed.

Referring to FIG. 6E, the component 20 may be illuminated with a laser LA1 in a laser irradiation process to form a modified layer (or a stealth dicing (SD) layer) inside the component 20. The modified layer may include cracks. Afterwards, the component 20 may be applied with external force via the dicing tape 93 in an expansion process to extend the cracks in the modified layer to the surface of the component 20 and separate the component 20 as shown in FIG. 6F.

Referring to FIG. 6F, a section 27a of the component 20 and a section 27b of the component 20 with the component 60 may be formed after the laser irradiation process and the expansion process. In some embodiments, the sections 27a and 27b may be formed through various dicing techniques.

Referring to FIG. 6G, the section 27a may be detached from the dicing tape 90 and then attached to a carrier 10 to define the regions A1, B1, and V1. A protective material may be formed between the component 20 and the carrier to cover the interconnection elements 70 to form the semiconductor package device 1, 2A, 2B, 2C, 2D, 2E, 2F, or 2G.

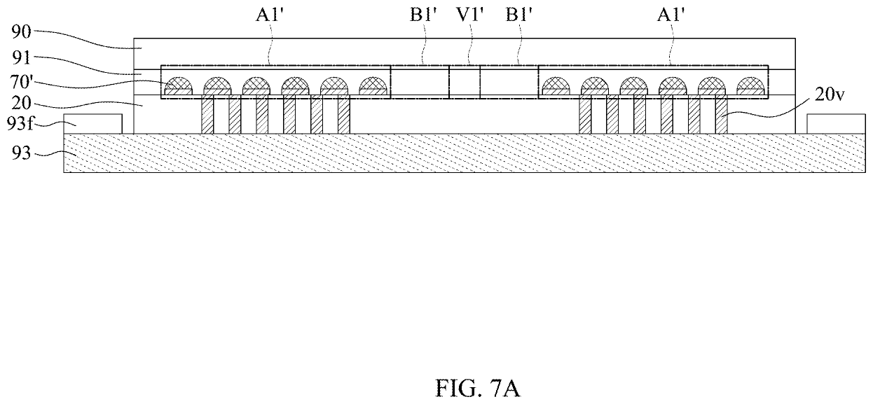

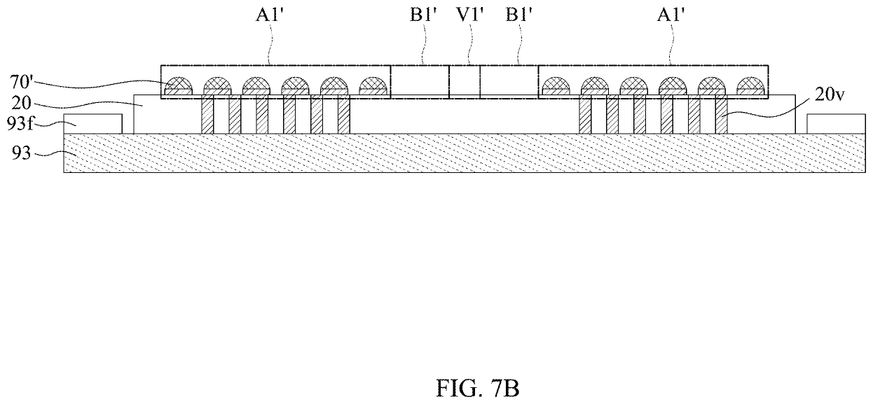

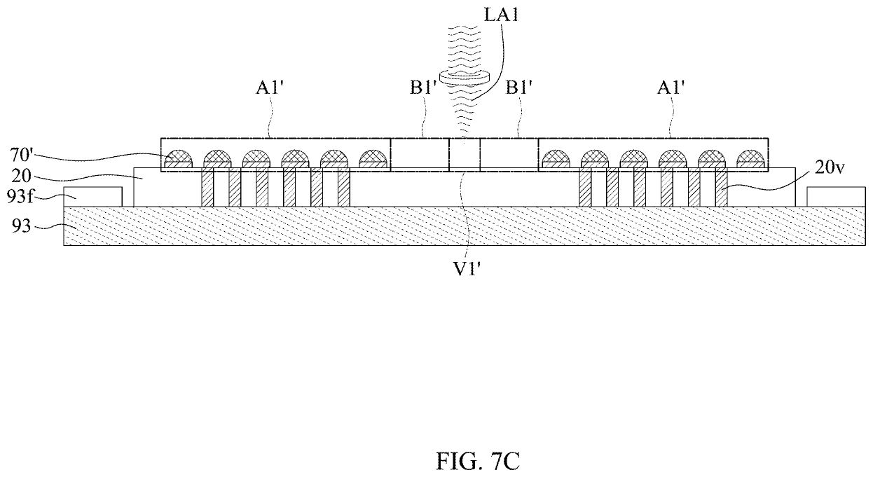

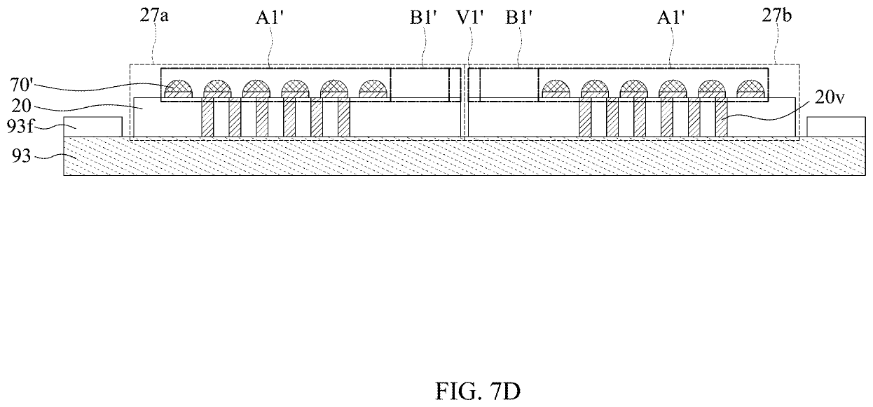

FIGS. 7A, 7B, 7C, and 7D illustrate a method for manufacturing a semiconductor device package according to some embodiments of the present disclosure. In some embodiments, the method is for manufacturing the semiconductor device package 1, 2A, 2B, 2C, 2D, 2E, 2F, or 2G.

The step of FIG. 7A may follow the step of FIG. 6A. Referring to FIG. 7A, the component 20 may be directly attached to a dicing tape 93 via an adhesive layer (not shown).

Referring to FIG. 7B, the temporary carrier 90 and the adhesive layer 91 may be removed.

Referring to FIG. 7C, the component 20 may be illuminated with a laser LA1 in a laser irradiation process to form a modified layer (or a stealth dicing (SD) layer) inside the component 20. The modified layer may include cracks. Afterwards, the component 20 may be applied with external force via the dicing tape 93 in an expansion process to extend the cracks in the modified layer to the surface of the component 20 and separate the component 20 as shown in FIG. 7D.

Referring to FIG. 7D, a section 27a of the component 20 and a section 27b of the component 20 may be formed after the laser irradiation process and the expansion process. In some embodiments, the sections 27a and 27b may be formed through other various dicing techniques.

A step similar to that of FIG. 6G may follow the step of FIG. 7D to form the semiconductor package device 1, 2A, 2B, 2C, 2D, 2E, 2F, or 2G.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to +0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A package, comprising:
a carrier;
a component disposed over the carrier and having a side surface configured for optically coupling; and
a first protective element disposed between the carrier and the component,
wherein the side surface of the component is free from being in contact with the first protective element.

2. The package of claim 1, further comprising an optical fiber optically coupled with the component through the side surface of the component.

3. The package of claim 2, further comprising a second protective element encapsulating a coupling end of the optical fiber, wherein the second protective element is free from being in contact with the first protective element.

4. The package of claim 1, wherein the first protective element is free from being in contact with a side surface of the carrier.

5. The package of claim 4, further comprising a plurality of interconnection elements encapsulated by the first protective element, wherein the first protective element has an edge under a first region of the component, wherein the first region is between the side surface of the component and a second region of the component, and the plurality of interconnection elements are under the second region of the component.

6. The package of claim 1, further comprising:
a blocking structure region having a top surface or a bottom surface under a lower surface of the component, wherein the top surface of the bottom surface of the blocking structure region is at an elevation different from that of an upper surface of the carrier.

7. The package of claim 6, wherein the bottom surface of the blocking structure region is lower than the upper surface of the carrier.

8. The package of claim 7, wherein the carrier comprises a solder resist layer at the upper surface of the carrier, wherein the bottom surface of the blocking structure region is recessed from an upper surface of the solder resist layer.

9. A semiconductor package, comprising:
a carrier;
a component disposed over the carrier and having a side surface configured for external communication; and
a plurality of interconnection elements connecting the carrier and the component, and encapsulated by a protection element;
wherein the side surface of the component is free from being in contact with the protective element.

10. The semiconductor package of claim 9, further comprising a first region defined by overlapping between the carrier and the component and comprising a first sub-region and a second sub-region, wherein a first group of the interconnection elements is formed in the first sub-region and is electrically functional, and a second group of the interconnection elements is formed in the second sub-region and is configured to support the component.

11. The semiconductor package of claim 10, wherein the second group of the interconnection elements comprises at least a dummy die.

12. The semiconductor package of claim 10, wherein the second group of the interconnection elements comprises at least a dummy bump.

13. The semiconductor package of claim 9, further comprising a second region between the carrier and the component, the second region is defined by position arrangement of the plurality of interconnection elements and accommodates none of the plurality of interconnection elements, wherein a trench is disposed in the second region and has a first length greater than a second length of the component from a top view perspective.

14. The semiconductor package of claim 9, further comprising a second region between the carrier and the component, the second region is defined by position arrangement of the plurality of interconnection elements and accommodates none of the plurality of interconnection elements, wherein a trench is disposed in the second region and has a depth and a width greater than the depth.

15. The semiconductor package of claim 9, further comprising a second region between the carrier and the component, the second region is defined by position arrangement of the plurality of interconnection elements and accommodates none of the plurality of interconnection elements, wherein the component has an overhang portion adjacent to the side surface of the component, wherein a length of the second region is greater than a length of the overhang portion.

16. A semiconductor device package, comprising:
a carrier;
a component disposed over the carrier; and
a protective element between the carrier and the component,
wherein a region is defined by overlapping between the carrier and the component and comprises:
a first region, accommodating a plurality of interconnection elements encapsulated by the protective element; and
a second region, accommodating a portion of the protective element and none of the plurality of interconnection elements.

17. The semiconductor device package of claim 16, wherein an area of the first region is greater than an area of the second region.

18. The semiconductor device package of claim 16, wherein the first region further comprises a first sub-region and a second sub-region, and wherein a first group of the interconnection elements in the first sub-region is configured to transmit an electrical signal between the component and the carrier, and a second group of the interconnection elements in the second sub-region is configured to support the component.

19. The semiconductor device package of claim 16, further comprising a third region distinct from the first region and the second region, and accommodating none of any portion of the protective element and none of the plurality of interconnection elements.

20. The semiconductor device package of claim 16, further comprising a third region distinct from the first region and the second region, and accommodating at least a die configured to support the component.
